(19) United States
(12) Patent Application Publication
(10) Pub. No.: US 2024/0372509 A1
(43) Pub. Date: Nov. 7, 2024

(54) DOHERTY AMPLIFICATION CIRCUIT

(71) Applicant: Murata Manufacturing Co., Ltd., Kyoto (JP)

(72) Inventor: Kouhei JITOUSHO, Kyoto (JP)

(21) Appl. No.: 18/774,145

(22) Filed: Jul. 16, 2024

Related U.S. Application Data
(63) Continuation of application No. PCT/JP2023/003859, filed on Feb. 6, 2023.

(30) Foreign Application Priority Data
Feb. 24, 2022 (JP) 2022-026795

(51) Int. Cl. H03F 1/02; H03F 3/24

(52) U.S. Cl. CPC H03F 1/0288; H03F 3/24; H03F 2200/451

(57) ABSTRACT

A Doherty amplification circuit includes a carrier amplifier that is a single-stage or multistage amplifier, and a peak amplifier that is a multistage amplifier, in which the number of stages of the peak amplifier is larger than the number of stages of the carrier amplifier.

### CROSS REFERENCE TO RELATED APPLICATION

This is a continuation of International Application No. PCT/JP2023/003859 filed on Feb. 6, 2023 which claims priority from Japanese Patent Application No. 2022-026795 filed on Feb. 24, 2022. The contents of these applications are incorporated herein by reference in their entireties.

### BACKGROUND ART

### Technical Field

The present disclosure relates to a Doherty amplification circuit.

### Background Art

Patent Document 1 discloses a Doherty amplification circuit including a first amplifier (carrier amplifier) that amplifies a first signal split from an input signal in a region in which a power level of the input signal is equal to or higher than a first level, to output a second signal, and a second amplifier (peak amplifier) that amplifies a third signal split from the input signal in a region in which the power level of the input signal is equal to or higher than a second level higher than the first level, to output a fourth signal.
Patent Document 1: Japanese Unexamined Patent Application Publication No. 2018-137566

### BRIEF SUMMARY

However, in the configuration of Patent Document 1, in a case where the peak amplifier is changed between an on-state and an off-state, the change in the gain with respect to the output power of the Doherty amplification circuit is increased, and the characteristics of the Doherty amplification circuit may be deteriorated.

Therefore, the present disclosure provides a Doherty amplification circuit that can suppress deterioration in characteristics by suppressing a change in gain with respect to output power.

An aspect of the present disclosure provides a Doherty amplification circuit including: a carrier amplifier that is a single-stage or multistage amplifier; and a first peak amplifier that is a multistage amplifier, in which the number of stages of the first peak amplifier is larger than the number of stages of the carrier amplifier.

With the Doherty amplification circuit according to the aspect of the present disclosure, it is possible to suppress the deterioration in the characteristics by suppressing the change in the gain with respect to the output power.

### BRIEF DESCRIPTION OF THE DRAWINGS

FIG. 1 is a circuit configuration diagram of a communication device according to Embodiment 1.

FIG. 2A is a circuit configuration diagram of a carrier amplifier according to Embodiment 1.

FIG. 2B is a circuit configuration diagram of a peak amplifier according to Embodiment 1.

FIG. 3A is a graph illustrating a change in gain with respect to output power of a Doherty amplification circuit according to Comparative Example 1.

FIG. 3B is a graph illustrating a change in gain with respect to output power of a Doherty amplification circuit according to Embodiment 1.

FIG. 4 is a plan view of the Doherty amplification circuit according to Embodiment 1.

FIG. 5 is a cross-sectional view of the Doherty amplification circuit according to Embodiment 1.

FIG. 6 is a cross-sectional view of the Doherty amplification circuit according to Embodiment 1.

FIG. 7 is a circuit configuration diagram of a Doherty amplification circuit according to Modification Example 1 of Embodiment 1.

FIG. 8 is a circuit configuration diagram of a Doherty amplification circuit according to Modification Example 2 of Embodiment 1.

FIG. 9 is a circuit configuration diagram of a communication device according to Embodiment 2.

FIG. 10A is a circuit configuration diagram of a carrier amplifier according to Embodiment 2.

FIG. 10B is a circuit configuration diagram of a first peak amplifier according to Embodiment 2.

FIG. 10C is a circuit configuration diagram of a second peak amplifier according to Embodiment 2.

FIG. 11A is a graph illustrating a change in gain with respect to output power of a Doherty amplification circuit according to Comparative Example 2.

FIG. 11B is a graph illustrating a change in gain with respect to output power of a Doherty amplification circuit according to Embodiment 2.

FIG. 12 is a plan view of an integrated circuit in which the carrier amplifier, the first peak amplifier, and the second peak amplifier according to Embodiment 2 are mounted.

FIG. 13 is a circuit configuration diagram of a Doherty amplification circuit according to Modification Example 1 of Embodiment 2.

FIG. 14 is a circuit configuration diagram of a Doherty amplification circuit according to Modification Example 2 of Embodiment 2.

FIG. 15 is a circuit configuration diagram of a communication device according to Embodiment 3.

FIG. 16 is a circuit configuration diagram of a second peak amplifier according to Embodiment 3.

FIG. 17 is a graph illustrating a change in gain with respect to output power of a Doherty amplification circuit according to Embodiment 3.

FIG. 18 is a plan view of an integrated circuit according to Embodiment 3.

### DETAILED DESCRIPTION

Hereinafter, embodiments of the present disclosure will be described in detail with reference to the drawings. The embodiments described below are all inclusive or specific examples. Numerical values, shapes, materials, constituent elements, disposition and connection form of constituent elements, and the like shown in the following embodiments are examples and are not intended to limit the gist of the present disclosure.

Each drawing is a schematic diagram in which appropriate emphasis, omission, or adjustment of a ratio is made for the purpose of showing the present disclosure, and is not necessarily strictly shown, and may be different from the actual shape, positional relationship, and ratio. In each drawing, substantially the same configurations are denoted by the same reference numerals, and the duplicate description may be omitted or simplified.

In the circuit configuration of the present disclosure, the expression “connected” means a case of being electrically connected with another circuit element interposed therebetween, as well as a case of being directly connected by a connection terminal and/or a wiring conductor. The expression “connected between A and B” means connection to both A and B between A and B, and includes serial connection to a path connecting A and B, as well as parallel connection (shunt connection) between the path and a ground.

In the component disposition of the present disclosure, the expression “a component is disposed on a substrate” means that the component is disposed on a main surface of the substrate and that the component is disposed in the substrate. The expression “the component is disposed on the main surface of the substrate” means that the component is disposed above the main surface without necessarily being in contact with the main surface (for example, the component is laminated on another component disposed in contact with the main surface), in addition to meaning that the component is disposed in contact with the main surface of the substrate. The expression “the component is disposed on the main surface of the substrate” may mean that the component is disposed in a recess portion formed in the main surface. The expression “the component is disposed in the substrate” means that the entire component is disposed between both main surfaces of the substrate, but a part of the component is not covered with the substrate, and only a part of the component is disposed in the substrate, in addition to meaning that the component is encapsulated in a module substrate.

In the component disposition of the present disclosure, the expression “in plan view of the module substrate” means that an object is viewed in an orthogonal projection from a z-axis positive side to an xy plane. The terms such as “parallel” and “perpendicular”, representing a relationship between elements, the term such as “rectangular” representing a shape of the element, and a numerical value range mean not only their exact meaning but also a substantially equivalent range, for example, the inclusion of an error of about a few percent.

### Embodiment 1

Hereinafter, Embodiment 1 will be described.

### 1.1 Circuit Configuration of Communication Device 5

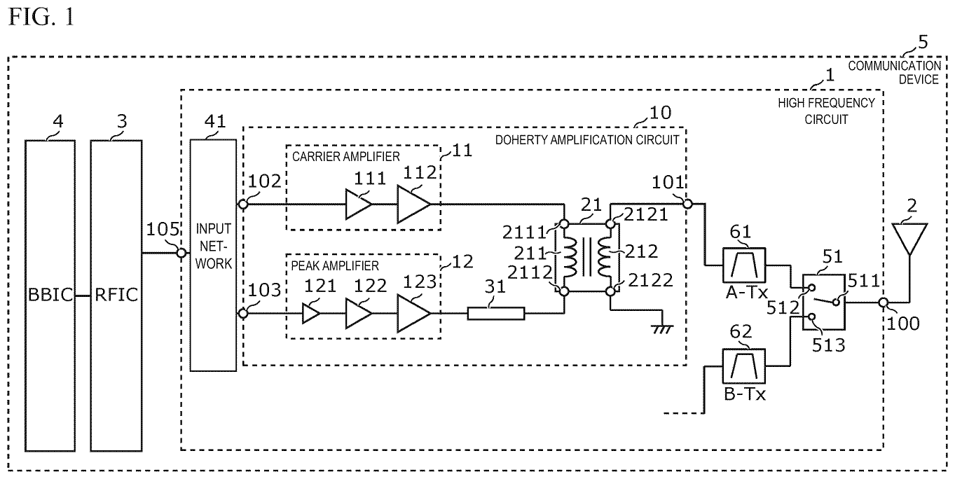

First, a circuit configuration of a communication device 5 according to the present embodiment will be described with reference to FIG. 1. FIG. 1 is a circuit configuration diagram of the communication device 5 according to the present embodiment.

The communication device 5 corresponds to a user equipment (UE) in a cellular network, and is typically a cellular phone, a smartphone, a tablet computer, a wearable device, or the like. The communication device 5 may be an internet-of-things (IoT) sensor device, a medical/healthcare device, a car, an unmanned aerial vehicle (UAV) (so-called drone), or an automated guided vehicle (AGV).

As illustrated in FIG. 1, the communication device 5 includes a high frequency circuit 1, an antenna 2, a radio frequency integrated circuit (RFIC) 3, and a baseband integrated circuit (BBIC) 4.

The high frequency circuit 1 can transmit a high frequency signal between the antenna 2 and the RFIC 3. An internal configuration of the high frequency circuit 1 will be described below.

The antenna 2 is connected to an antenna connection terminal 100 of the high frequency circuit 1, and transmits the high frequency signal output from the high frequency circuit 1. The antenna 2 may receive the high frequency signal from the outside to output the high frequency signal to the high frequency circuit 1.

The RFIC 3 is an example of a signal processing circuit that processes the high frequency signal. Specifically, the RFIC 3 performs signal processing on a transmission signal input from the BBIC 4 by up-conversion or the like, and outputs a high frequency transmission signal generated by the signal processing to a transmission path of the high frequency circuit 1. The RFIC 3 includes a control unit that controls the high frequency circuit 1. Some or all of the functions of the control unit of the RFIC 3 may be implemented outside the RFIC 3, and may be implemented in, for example, the BBIC 4 or the high frequency circuit 1.

The BBIC 4 is a baseband signal processing circuit that performs signal processing using an intermediate frequency band having a lower frequency than the high frequency signal transmitted by the high frequency circuit 1. For example, an image signal for image display and/or an audio signal for a call via a speaker is used as the signal processed by the BBIC 4.

The circuit configuration of the communication device 5 represented in FIG. 1 is an example, and the circuit configuration thereof is not limited thereto. For example, the communication device 5 need not include the antenna 2 and/or the BBIC 4. Further, for example, the communication device 5 may include a plurality of antennas.

### 1.2 Circuit Configuration of High Frequency Circuit 1

Next, a circuit configuration of the high frequency circuit 1 included in the communication device 5 will be described with reference to FIG. 1. As illustrated in FIG. 1, the high frequency circuit 1 includes a Doherty amplification circuit 10, an input network 41, a switch 51, filters 61 and 62, the antenna connection terminal 100, and an RFIC connection terminal 105. Hereinafter, the constituent elements of the high frequency circuit 1 will be described in order.

The antenna connection terminal 100 is connected to the switch 51 in the high frequency circuit 1, and is connected to the antenna 2 outside the high frequency circuit 1. A transmission signal of a band A amplified by the Doherty amplification circuit 10 is output to the antenna 2 via the antenna connection terminal 100.

The RFIC connection terminal 105 is a terminal for receiving the transmission signal of the band A from the RFIC 3. The RFIC connection terminal 105 is connected to the RFIC 3 outside the high frequency circuit 1, and is connected to the input network 41 inside the high frequency circuit 1.

The input network 41 is connected between the RFIC connection terminal 105 and input terminals 102 and 103 of the Doherty amplification circuit 10. The input network 41 functions as a power splitter and also functions as a phase shifter in the present embodiment. For example, a quadrature coupler or the like can be used as the input network 41.

Specifically, the input network 41 splits the transmission signal of the band A received via the RFIC connection terminal 105 into two signals, and outputs the split two signals (split signals) of the band A to the respective input terminals 102 and 103 of the Doherty amplification circuit 10. In this case, the input network 41 adjusts phases of the two split signals of the band A. For example, the input network 41 shifts the split signal of the band A output to the input terminal 102 by −90 degrees (delays the split signal of the band A output to the input terminal 102 by 90 degrees) from the input signal, and does not shift the split signal of the band A output to the input terminal 103 from the input signal.

A shift amount of the phase in the input network 41 is not limited to the above-described example. It is sufficient that a relative phase difference between the two split signals is maintained, and the shift amounts of the phases of the two split signals may be, for example, 0 degrees and +90 degrees. In addition, the phase difference between the two split signals may also be changed as appropriate based on an internal configuration of the Doherty amplification circuit 10.

The Doherty amplification circuit 10 can amplify the transmission signal of the band A. A circuit configuration of the Doherty amplification circuit 10 will be described below.

The Doherty amplification circuit means an amplification circuit that realizes high efficiency by using a plurality of amplifiers as a carrier amplifier and a peak amplifier. The carrier amplifier means an amplifier that operates even in a case where the power of the high frequency signal (input) is low or high in the Doherty amplification circuit. The peak amplifier means an amplifier that mainly operates in a case where the power of the high frequency signal (input) is high in the Doherty amplification circuit. Therefore, the high frequency signal is mainly amplified by the carrier amplifier in a case where the input power of the high frequency signal is low, and the high frequency signals are amplified by the carrier amplifier and the peak amplifier and are combined in a case where the input power of the high frequency signal is high. With such an operation, in the Doherty amplification circuit, a load impedance as viewed from the carrier amplifier is increased at the low output power, and the efficiency at the low output power is improved. In a case where the output signals of the plurality of amplifiers are subjected to voltage-combining in the Doherty amplification circuit, an amplifier of which an output terminal is connected to the phase shift circuit among the plurality of amplifiers can be specified as the peak amplifier, and an amplifier of which an output terminal is not connected to the phase shift circuit among the plurality of amplifiers can be specified as the carrier amplifier. On the other hand, in a case where the output signals of the plurality of amplifiers are subjected to current-combining in the Doherty amplification circuit, an amplifier of which an output terminal is connected to the phase shift circuit among the plurality of amplifiers can be specified as the carrier amplifier, and an amplifier of which an output terminal is not connected to the phase shift circuit among the plurality of amplifiers can be specified as the peak amplifier.

The switch 51 is connected between the antenna connection terminal 100, and the filters 61 and 62. The switch 51 includes terminals 511 to 513. The terminal 511 is connected to the antenna connection terminal 100. The terminal 512 is connected to the filter 61. The terminal 513 is connected to the filter 62.

With this connection configuration, the switch 51 can connect the terminal 511 to at least one of the terminals 512 and 513, for example, based on a control signal from the RFIC 3.

The filter 61 (A-Tx) has a pass band including the band A. The filter 61 is connected between the antenna connection terminal 100 and the Doherty amplification circuit 10. Specifically, one end of the filter 61 is connected to the antenna connection terminal 100 with the switch 51 interposed therebetween, and the other end of the filter 61 is connected to the Doherty amplification circuit 10.

The filter 62 (B-Tx) has a pass band including a band B. The filter 62 is connected between the antenna connection terminal 100 and a power amplification circuit (not illustrated). Specifically, one end of the filter 62 is connected to the antenna connection terminal 100 with the switch 51 interposed therebetween, and the other end of the filter 62 is connected to the power amplification circuit. In this case, the power amplification circuit may be a Doherty amplification circuit similar to the Doherty amplification circuit 10.

The bands A and B are frequency bands for a communication system constructed using a radio access technology (RAT). The bands A and B are defined in advance by a standards organization and the like (for example, 3rd generation partnership project (3GPP) (registered trademark), institute of electrical and electronics engineers (IEEE), and the like). Examples of the communication system include a 5G NR system, an LTE system, and a wireless local area network (WLAN) system.

The high frequency circuit 1 represented in FIG. 1 is an example, and the high frequency circuit 1 is not limited thereto. For example, the high frequency circuit 1 need not include the filter 62 and the switch 51. In addition, the high frequency circuit 1 need not include the input network 41. In this case, the RFIC 3 may perform the power splitter and the phase adjustment of the transmission signal of the band A. The high frequency circuit 1 may include a reception path. Further, for example, the high frequency circuit 1 may include a filter and a power amplification circuit corresponding to a band C different from the bands A and B.

### 1.3 Circuit Configuration of Doherty Amplification Circuit 10

Next, the circuit configuration of the Doherty amplification circuit 10 included in the high frequency circuit 1 will be described with reference to FIG. 1. The Doherty amplification circuit 10 includes a carrier amplifier 11, a peak amplifier 12, a transformer 21, a phase shift circuit 31, an output terminal 101, and the input terminals 102 and 103. Hereinafter, the constituent elements of the Doherty amplification circuit 10 will be described in order.

The input terminals 102 and 103 are terminals for receiving the signal from the input network 41. The transmission signal of the band A output from the input network 41 is input to the carrier amplifier 11 and the peak amplifier 12 with the input terminal 102 and the input terminal 103 interposed therebetween.

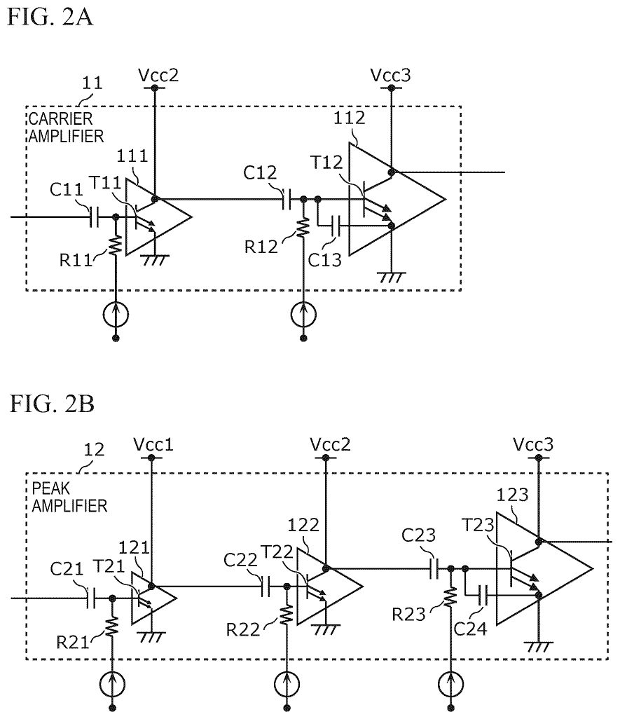

The carrier amplifier 11 is a multistage amplifier, and includes a first stage 111 (drive stage or input stage) and a final stage 112 (power stage or output stage). Therefore, in the present embodiment, the number of stages of the carrier amplifier 11 is two. The carrier amplifier 11 can operate in, for example, a class-A or a class-AB to amplify the high frequency signal received via the input terminal 102. A circuit configuration of the carrier amplifier 11 will be described below with reference to FIG. 2A.

The peak amplifier 12 is an example of a first peak amplifier. The peak amplifier 12 is a multistage amplifier, and includes a first stage 121 (drive stage or input stage), a second stage 122, and a final stage 123 (power stage or output stage). Therefore, in the present embodiment, the number of stages of the peak amplifier 12 is three, which is larger than the number of stages of the carrier amplifier 11. The peak amplifier 12 can operate in, for example, a class-C to amplify the high frequency signal received via the input terminal 103. A circuit configuration of the peak amplifier 12 will be described below with reference to FIG. 2B.

The multistage amplifier means an amplifier including two or more single-stage amplifiers that are cascading-connected. In this case, the number of stages of the multistage amplifier means the number of single-stage amplifiers that are cascading-connected. The cascading connection means that an output terminal of a certain stage is connected to an input terminal of a next stage. That is, in the multistage amplifier, an input terminal of one of the two or more single-stage amplifiers is connected to an output terminal of the other of the two or more single-stage amplifiers. Here, the single-stage amplifier means an amplifier including only a single amplification transistor or two or more amplification transistors that are connected in parallel. The parallel connection between two or more amplification transistors means that input terminals (for example, base terminals) of the two or more amplification transistors are connected to each other and output terminals (for example, collector terminals) of the two or more amplification transistors are connected to each other.

The transformer 21 includes an input side coil 211 and an output side coil 212. One end 2111 of the input side coil 211 is connected to an output terminal of the carrier amplifier 11. The other end 2112 of the input side coil 211 is connected to an output terminal of the peak amplifier 12 with the phase shift circuit 31 interposed therebetween. One end 2121 of the output side coil 212 is connected to the output terminal 101. The other end 2122 of the output side coil 212 is connected to the ground. With this connection configuration, the transformer 21 can perform voltage-combining of the output signal of the carrier amplifier 11 and the output signal of the peak amplifier 12.

The phase shift circuit 31 is connected between the output terminal of the peak amplifier 12 and the transformer 21. The phase shift circuit 31 can shift the phase of the signal of the band A output from the peak amplifier 12 by −90 degrees (delay the phase of the signal of the band A output from the peak amplifier 12 by 90 degrees). For example, a ¼ wavelength transmission line can be used as the phase shift circuit 31. The phase shift circuit 31 may include an inductor and/or a capacitor. As a result, the phase shift circuit 31 can shorten a line length.

The Doherty amplification circuit 10 represented in FIG. 1 is an example, and the Doherty amplification circuit 10 is not limited thereto. For example, the Doherty amplification circuit 10 may include a part or all of the input network 41. In addition, the number of stages of the carrier amplifier 11 and the peak amplifier 12 is not limited to two and three. The number of stages of the carrier amplifier 11 may be one, three, four, five, or six or more. In addition, the number of stages of the peak amplifier 12 may be any number as long as the number of stages is larger than the number of stages of the carrier amplifier 11. A difference between the number of stages of the carrier amplifier 11 and the number of stages of the peak amplifier 12 is not limited to one, and may be two, three, four, five, or six or more. The number of stages of the carrier amplifier 11 may be even, and the number of stages of the peak amplifier 12 may be odd. The number of stages of both the carrier amplifier 11 and the peak amplifier 12 may be odd or even. That is, in the present embodiment, it is sufficient that the condition of “the number of stages of the carrier amplifiers 11<the number of stages of the peak amplifiers 12” is satisfied.

### 1.4 Circuit Configurations of Carrier Amplifier 11 and Peak Amplifier 12

Next, the circuit configurations of the carrier amplifier 11 and the peak amplifier 12 included in the Doherty amplification circuit 10 will be described in order.

First, the carrier amplifier 11 will be described with reference to FIG. 2A. FIG. 2A is a circuit configuration diagram of the carrier amplifier 11 according to the present embodiment. The carrier amplifier 11 includes amplification transistors T11 and T12, capacitors C11 to C13, and resistors R11 and R12.

The amplification transistor T11 is a bipolar transistor including a base terminal, a collector terminal, and an emitter terminal, and constitutes the first stage 111 of the carrier amplifier 11. The base terminal of the amplification transistor T11 is connected to an input terminal of the carrier amplifier 11 with the capacitor C11 interposed therebetween, and is connected to a current source with the resistor R11 interposed therebetween. The collector terminal of the amplification transistor T11 is connected to a terminal to which a power supply voltage Vcc2 is applied, and is connected to an input terminal of the final stage 112. The emitter terminal of the amplification transistor T11 is connected to the ground.

The amplification transistor T12 is a bipolar transistor including a base terminal, a collector terminal, and an emitter terminal, and constitutes the final stage 112 of the carrier amplifier 11. The base terminal of the amplification transistor T12 is connected to an output terminal of the first stage 111 of the carrier amplifier 11 with the capacitor C12 interposed therebetween, and is connected to the current source with the resistor R12 interposed therebetween. The collector terminal of the amplification transistor T12 is connected to a terminal to which a power supply voltage Vcc3 is applied, and is connected to the output terminal of the carrier amplifier 11. The emitter terminal of the amplification transistor T12 is connected to the base terminal with the capacitor C13 interposed therebetween, and is connected to the ground.

Next, the peak amplifier 12 will be described with reference to FIG. 2B. FIG. 2B is a circuit configuration diagram of the peak amplifier 12 according to the present embodiment. The peak amplifier 12 includes amplification transistors T21 to T23, capacitors C21 to C24, and resistors R21 to R23.

The amplification transistor T21 is a bipolar transistor including a base terminal, a collector terminal, and an emitter terminal, and constitutes the first stage 121 of the peak amplifier 12. The base terminal of the amplification transistor T21 is connected to an input terminal of the peak amplifier 12 with the capacitor C21 interposed therebetween, and is connected to the current source with the resistor R21 interposed therebetween. The collector terminal of the amplification transistor T21 is connected to a terminal to which a power supply voltage Vcc1 is applied, and is connected to an input terminal of the second stage 122. The emitter terminal of the amplification transistor T21 is connected to the ground.

The amplification transistor T22 is a bipolar transistor including a base terminal, a collector terminal, and an emitter terminal, and constitutes the second stage 122 of the peak amplifier 12. The base terminal of the amplification transistor T22 is connected to an output terminal of the first stage 121 with the capacitor C22 interposed therebetween, and is connected to the current source with the resistor R22 interposed therebetween. The collector terminal of the amplification transistor T22 is connected to the terminal to which the power supply voltage Vcc2 is applied, and is connected to an input terminal of the final stage 123. The emitter terminal of the amplification transistor T22 is connected to the ground.

The amplification transistor T23 is a bipolar transistor including a base terminal, a collector terminal, and an emitter terminal, and constitutes the final stage 123 of the peak amplifier 12. The base terminal of the amplification transistor T23 is connected to an output terminal of the second stage 122 with the capacitor C23 interposed therebetween, and is connected to the current source with the resistor R23 interposed therebetween. The collector terminal of the amplification transistor T23 is connected to the terminal to which the power supply voltage Vcc3 is applied, and is connected to the output terminal of the peak amplifier 12. The emitter terminal of the amplification transistor T23 is connected to the base terminal with the capacitor C24 interposed therebetween, and is connected to the ground.

The circuit configurations of the carrier amplifier 11 and the peak amplifier 12 represented in FIGS. 2A and 2B are examples, and the circuit configurations thereof are not limited thereto. For example, each of the amplification transistors T11, T12, and T21 to T23 may be a field effect transistor including a drain, a source, and a gate. Further, for example, an impedance matching circuit may be inserted between the stages in the carrier amplifier 11 and/or the peak amplifier 12. In this case, the impedance matching circuit may include an inductor and/or a capacitor, or may include a transformer.

### 1.5 Gain of Doherty Amplification Circuit 10

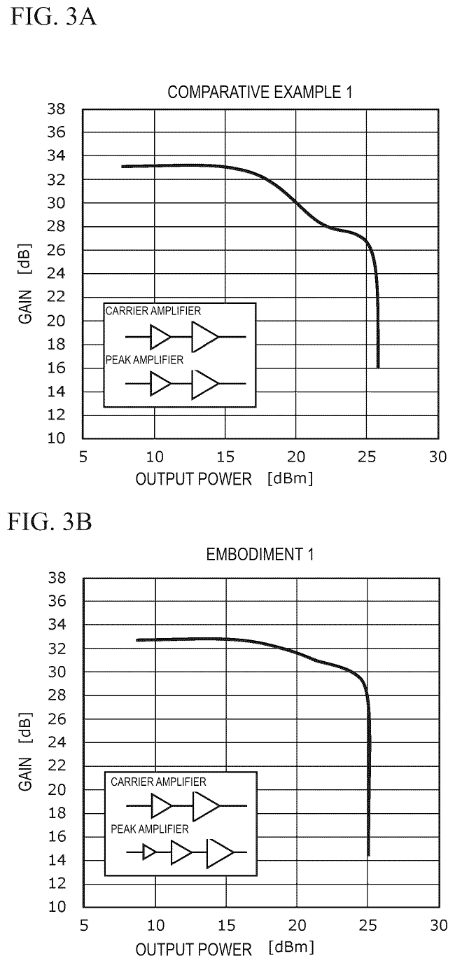

Next, gain of the Doherty amplification circuit 10 configured as described above will be described with reference to FIGS. 3A and 3B. FIG. 3A is a graph illustrating a change in gain with respect to output power of a Doherty amplification circuit according to Comparative Example 1. FIG. 3B is a graph illustrating a change in the gain with respect to the output power of the Doherty amplification circuit 10 according to the present embodiment. In FIGS. 3A and 3B, a horizontal axis represents the output power (dBm), and a vertical axis represents the gain (dB). The Doherty amplification circuit according to Comparative Example 1 has the same configuration as that of the present embodiment, except that the carrier amplifier and the peak amplifier have the equal number of stages, that is, two.

In Comparative Example 1, as illustrated in FIG. 3A, the change in the gain with respect to the output power is large in the vicinity of the output power of 20 dBm at which an on-state and an off-state of the peak amplifier are switched. That is, a decrease amount of the gain of the Doherty amplification circuit in a case where the peak amplifier is switched from the off-state to the on-state is large. In other words, an increase amount of the gain of the Doherty amplification circuit in a case where the peak amplifier is switched from the on-state to the off-state is large.

On the other hand, in the present embodiment, the gain of the peak amplifier 12 in the vicinity of the output power of 20 dBm is increased as the number of stages of the peak amplifier 12 is increased. Therefore, in the present embodiment, as illustrated in FIG. 3B, the change in the gain with respect to the output power in the vicinity of the output power of 20 dBm is smaller than that in Comparative Example 1. That is, in the present embodiment, the decrease amount of the gain of the Doherty amplification circuit 10 in a case where the peak amplifier 12 is switched from the off-state to the on-state is smaller than that in Comparative Example 1. Conversely, in the present embodiment, the increase amount of the gain of the Doherty amplification circuit 10 in a case where the peak amplifier 12 is switched from the on-state to the off-state is smaller than that in Comparative Example 1.

As described above, the Doherty amplification circuit 10 according to the present embodiment can suppress the change in the gain with respect to the output power as compared with the Doherty amplification circuit according to Comparative Example 1. As a result, the Doherty amplification circuit 10 according to the present embodiment can suppress the deterioration in the characteristics as compared with the Doherty amplification circuit according to Comparative Example 1.

### 1.6 Mounting Example of Doherty Amplification Circuit 10

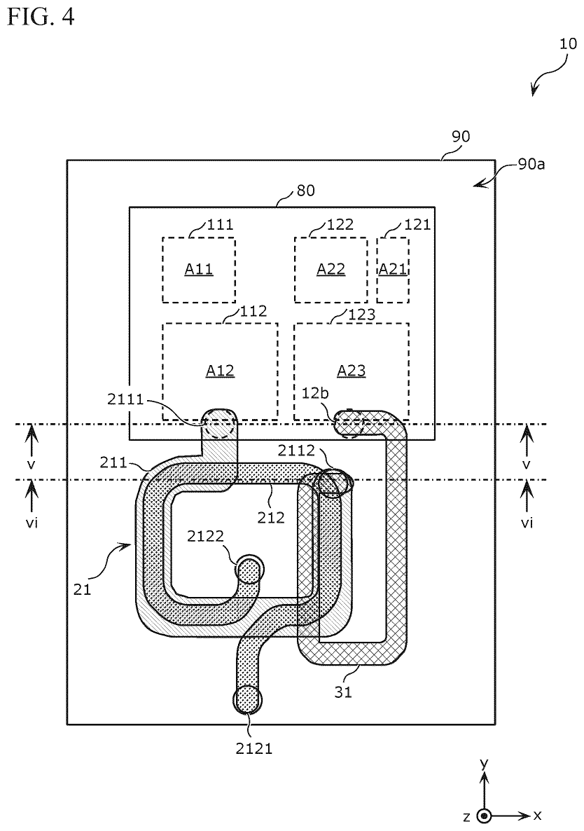

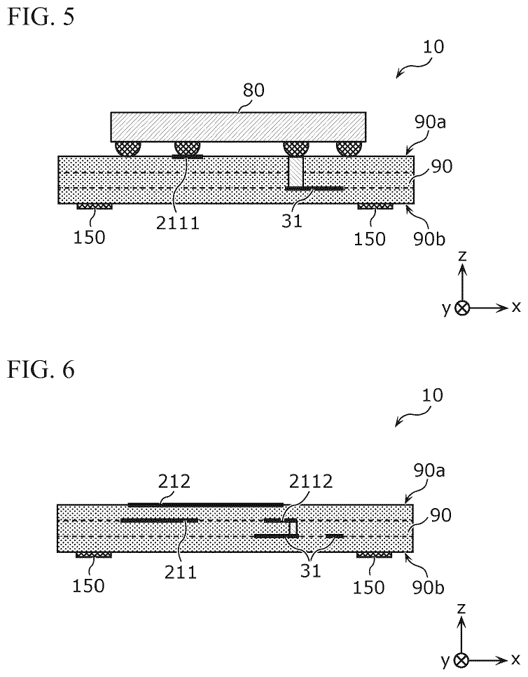

Next, a mounting example of the Doherty amplification circuit 10 will be described with reference to FIGS. 4 to 6. FIG. 4 is a plan view of the Doherty amplification circuit 10 according to the present embodiment. FIGS. 5 and 6 are cross-sectional views of the Doherty amplification circuit 10 according to the present embodiment. The cross sections of the Doherty amplification circuit 10 in FIGS. 5 and 6 are respective cross sections taken along a line v-v and a line vi-vi in FIG. 4. In FIGS. 4 to 6, a wiring for connecting a plurality of circuit components disposed on a module substrate 90 to each other is not illustrated. In FIG. 4, the transformer 21 and the phase shift circuit 31 in the module substrate 90 are also illustrated.

The Doherty amplification circuit 10 includes the module substrate 90, an integrated circuit 80, and a plurality of land electrodes 150, in addition to the plurality of circuit components illustrated in FIG. 1.

The module substrate 90 has main surfaces 90a and 90b facing each other. In FIG. 4, the module substrate 90 has a rectangular shape in plan view, but the module substrate 90 is not limited to this shape.

As the module substrate 90, for example, a low temperature co-fired ceramics (LTCC) substrate or a high temperature co-fired ceramics (HTCC) substrate having a laminated structure of a plurality of dielectric layers, a component-embedded substrate, a substrate having a redistribution layer (RDL), a printed board, or the like can be used, but the module substrate 90 is not limited thereto.

The integrated circuit 80, the transformer 21, and the phase shift circuit 31 are disposed on a main surface 90a of the module substrate 90 and in the module substrate 90, and the plurality of land electrodes 150 are disposed on a main surface 90b of the module substrate 90.

The integrated circuit 80 includes the carrier amplifier 11 and the peak amplifier 12. The integrated circuit 80 is composed of at least one of gallium arsenide (GaAs), silicon germanium (SiGe), or gallium nitride (GaN). The amplification transistors included in the carrier amplifier 11 and the peak amplifier 12 are mounted as, for example, a heterojunction bipolar transistor (HBT).

The integrated circuit 80 may be configured by using a complementary metal oxide semiconductor (CMOS), and may be manufactured by a silicon on insulator (SOI) process. In this case, the amplification transistors included in the carrier amplifier 11 and the peak amplifier 12 may be mounted as a field effect transistor (FET) such as a metal-oxide-semiconductor field effect transistor (MOSFET). A semiconductor material of the integrated circuit 80 is not limited to the above-described materials.

In FIG. 4, a region surrounded by a broken line represents a region in which the amplification transistor constituting each stage of the carrier amplifier 11 and the peak amplifier 12 in the integrated circuit 80 is formed. Specifically, in FIG. 4, the first stage 111 and the final stage 112 in the integrated circuit 80 respectively represent a region in which the amplification transistor T11 is formed and a region in which the amplification transistor T12 is formed. Similarly, the first stage 121, the second stage 122, and the final stage 123 in the integrated circuit 80 respectively represent a region in which the amplification transistor T21 is formed, a region in which the amplification transistor T22 is formed, and a region in which the amplification transistor T23 is formed.

A size of the final stage 112 of the carrier amplifier 11 is larger than a size of the first stage 111 of the carrier amplifier 11. That is, in plan view of the module substrate 90, an area of a region A12 in which the amplification transistor T12 is formed is larger than an area of a region A11 in which the amplification transistor T11 is formed.

A size of the final stage 123 of the peak amplifier 12 is larger than a size of each of the first stage 121 and the second stage 122 of the peak amplifier 12, and a size of the second stage 122 of the peak amplifier 12 is larger than a size of the first stage 121 of the peak amplifier 12. That is, in plan view of the module substrate 90, an area of a region A23 in which the amplification transistor T23 is formed in the integrated circuit 80 is larger than an area of a region A21 in which the amplification transistor T21 is formed in the integrated circuit 80, and is larger than an area of a region A22 in which the amplification transistor T22 is formed in the integrated circuit 80. Further, in plan view of the module substrate 90, the area of the region A22 in which the amplification transistor T22 is formed in the integrated circuit 80 is larger than the area of the region A21 in which the amplification transistor T21 is formed in the integrated circuit 80.

The size of the first stage 121 of the peak amplifier 12 is smaller than the size of the first stage 111 of the carrier amplifier 11. That is, in plan view of the module substrate 90, the area of the region A21 in which the amplification transistor T21 is formed in the integrated circuit 80 is smaller than the area of the region A11 in which the amplification transistor T11 is formed in the integrated circuit 80.

The size of the final stage 123 of the peak amplifier 12 is equal to the size of the final stage 112 of the carrier amplifier 11. That is, in plan view of the module substrate 90, the area of the region A23 in which the amplification transistor T23 is formed in the integrated circuit 80 is equal to the area of the region A12 in which the amplification transistor T12 is formed in the integrated circuit 80.

The size of the stage means the size of the region of the stage in the integrated circuit 80 in plan view of the module substrate 90, and is defined by a two-dimensional area. Here, the region of the stage means a region in which the amplification transistor constituting the stage is formed. The size of the stage can be measured by using an infrared microscope after the integrated circuit is polished.

In addition, the “sizes of two stages are equal” includes that the sizes of the two stages are substantially equal in addition to the strict match of the sizes of the two stages. The “sizes of the two stages are substantially equal” means that a ratio of a difference value of the two stages to a larger size among the sizes of the two stages is 10% or less.

The input side coil 211 and the output side coil 212 of the transformer 21 are formed by a plane wiring pattern in layers different from each other of the module substrate 90. Specifically, the output side coil 212 is disposed in a layer on the main surface 90a of the module substrate 90. The input side coil 211 is disposed in a layer in the module substrate 90. In plan view of the module substrate 90, at least a part of the input side coil 211 overlaps with at least a part of the output side coil 212.

The phase shift circuit 31 is disposed in the module substrate 90 and is configured by a planar wiring pattern. In FIG. 5, the phase shift circuit 31 is disposed in a layer on the main surface 90b side with respect to the transformer 21 (input side coil 211 and output side coil 212).

The plurality of land electrodes 150 function as a plurality of external connection terminals including a ground terminal in addition to the output terminal 101 and the input terminals 102 and 103 illustrated in FIG. 1. Each of the plurality of land electrodes 150 is disposed on the main surface 90b and connected to an input/output terminal and/or a ground terminal on a motherboard disposed in a z-axis negative direction of the Doherty amplification circuit 10. A plurality of bump electrodes may be disposed on the main surface 90b instead of the plurality of land electrodes 150.

The mounting examples of the Doherty amplification circuit 10 represented in FIGS. 4 to 6 are examples, and the mounting examples are not limited thereto. For example, the integrated circuit 80 may be divided into a plurality of integrated circuits. Further, for example, a bonding wire may be used as the phase shift circuit 31 instead of a planar wiring pattern in the module substrate 90. Further, for example, the main surface 90a of the module substrate 90 and the component on the main surface 90a may be covered with a resin member. As a result, reliability such as mechanical strength and moisture resistance of the component on the main surface 90a can be improved. Further, a surface of the resin member may be covered with, for example, a metal thin film (shield electrode layer) formed by a sputtering method. By connecting such a metal thin film to the ground, it is possible to suppress the entry of the external noise into the circuit components constituting the Doherty amplification circuit 10.

### 1.7 Effects

circuit 10 according to the present embodiment includes the carrier amplifier 11 that is a multistage amplifier and the peak amplifier 12 that is a multistage amplifier, and the number of stages of the peak amplifier 12 is larger than the number of stages of the carrier amplifier 11.

Accordingly, since the number of stages of the peak amplifier 12 is larger than the number of stages of the carrier amplifier 11, the gain of the peak amplifier 12 can be relatively increased. Therefore, it is possible to suppress the change in the gain of the Doherty amplification circuit 10 in a case where the on-state and the off-state of the peak amplifier 12 are switched. As a result, the linearity of the Doherty amplification circuit 10 can be improved, and the deterioration in the characteristics can be suppressed.

Further, for example, the Doherty amplification circuit 10 according to the present embodiment may include the module substrate 90 and at least one integrated circuit 80 that is disposed on the module substrate 90 and includes the amplification transistors T11, T12, and T21 to T23 of the carrier amplifier 11 and the peak amplifier 12, in which the size of the first stage 121 of the peak amplifier 12 may be smaller than the size of the first stage 111 of the carrier amplifier 11 in plan view of the module substrate 90.

Accordingly, the size of the first stage 121 of the peak amplifier 12 can be made relatively small, so that the increase in the size of the integrated circuit 80 due to the increase in the number of stages of the peak amplifier 12 can be suppressed.

Further, for example, in the Doherty amplification circuit 10 according to the present embodiment, in plan view of the module substrate 90, the size of the final stage 123 of the peak amplifier 12 may be equal to the size of the final stage 112 of the carrier amplifier 11.

Accordingly, the increase in the size of the final stage 123 of the peak amplifier 12 can be suppressed, and the decrease in the gain of the peak amplifier 12 can be suppressed. Therefore, it is possible to suppress the change in the gain of the Doherty amplification circuit 10 in a case where the on-state and the off-state of the peak amplifier 12 are switched. As a result, the linearity of the Doherty amplification circuit 10 can be improved, and the deterioration in the characteristics can be suppressed.

Further, for example, in the Doherty amplification circuit 10 according to the present embodiment of the present disclosure, one of the number of stages of the carrier amplifier 11 and the number of stages of the peak amplifier 12 may be odd, and the other of the number of stages of the carrier amplifier 11 and the number of stages of the peak amplifier 12 may be even.

Further, for example, the Doherty amplification circuit 10 according to the present embodiment may include the transformer 21 including the input side coil 211 and the output side coil 212, and the phase shift circuit 31 that is connected between the output terminal of the peak amplifier 12 and the transformer 21, in which one end 2111 of the input side coil 211 may be connected to the output terminal of the carrier amplifier 11, the other end 2112 of the input side coil 211 may be connected to the output terminal of the peak amplifier 12 with the phase shift circuit 31 interposed therebetween, one end 2121 of the output side coil 212 may be connected to the output terminal 101 of the Doherty amplification circuit 10, and the other end 2122 of the output side coil 212 may be connected to the ground.

Accordingly, the two signals (voltages) of the band A amplified by the carrier amplifier 11 and the peak amplifier 12 can be combined by using one transformer 21.

### Modification Example 1 of Embodiment 1

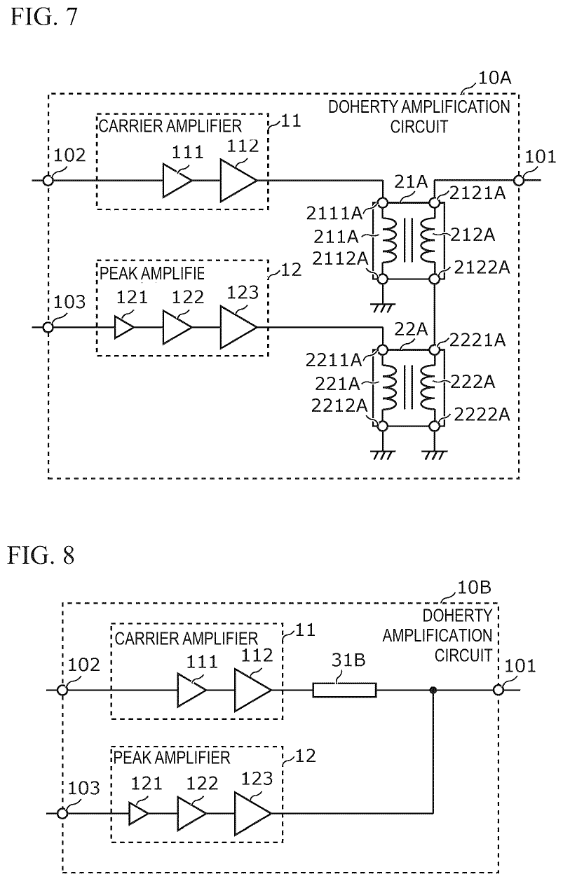

Next, Modification Example 1 of Embodiment 1 will be described. The present modification example is different from Embodiment 1 in that the output signal of the carrier amplifier 11 and the output signal of the peak amplifier 12 are combined by using two transformers. Hereinafter, the present modification example will be described with reference to FIG. 7, focusing on the difference from Embodiment 1.

FIG. 7 is a circuit configuration diagram of a Doherty amplification circuit 10A according to the present modification example. The Doherty amplification circuit 10A according to the present modification example is included in the high frequency circuit 1 of FIG. 1 instead of the Doherty amplification circuit 10.

As illustrated in FIG. 7, the Doherty amplification circuit 10A includes the carrier amplifier 11, the peak amplifier 12, transformers 21A and 22A, the output terminal 101, and the input terminals 102 and 103.

The transformer 21A is an example of a first transformer, and includes an input side coil 211A and an output side coil 212A. The input side coil 211A and the output side coil 212A are respective examples of a first input side coil and a first output side coil. One end 2111A of the input side coil 211A is connected to the output terminal of the carrier amplifier 11. The other end 2112A of the input side coil 211A is connected to the ground. One end 2121A of the output side coil 212A is connected to the output terminal 101. The other end 2122A of the output side coil 212A is connected to an output side coil 222A of the transformer 22A.

The transformer 22A is an example of a second transformer, and includes an input side coil 221A and the output side coil 222A. The input side coil 221A and the output side coil 222A are respective examples of a second input side coil and a second output side coil. One end 2211A of the input side coil 221A is connected to the output terminal of the peak amplifier 12. The other end 2212A of the input side coil 221A is connected to the ground. One end 2221A of the output side coil 222A is connected to the other end 2122A of the output side coil 212A of the transformer 21A. The other end 2222A of the output side coil 222A is connected to the ground.

With this connection configuration, the transformers 21A and 22A can perform voltage-combining of the output signal of the carrier amplifier 11 and the output signal of the peak amplifier 12.

In a case where the Doherty amplification circuit 10A according to the present modification example is included in the high frequency circuit 1, for example, the input network 41 shifts the split signal of the band A output to the input terminal 102 by −180 degrees (delays the split signal of the band A output to the input terminal 102 by 180 degrees) from the input signal, and does not shift the split signal of the band A output to the input terminal 103 from the input signal.

As described above, the Doherty amplification circuit 10A according to the present modification example includes the transformer 21A including the input side coil 211A and the output side coil 212A, and the transformer 22A including the input side coil 221A and the output side coil 222A, in which one end 2111A of the input side coil 211A is connected to the output terminal of the carrier amplifier 11, the other end 2112A of the input side coil 211A is connected to the ground, one end 2121A of the output side coil 212A is connected to the output terminal of the Doherty amplification circuit 10A, the other end 2122A of the output side coil 212A is connected to the output side coil 222A, one end 2211A of the input side coil 221A is connected to the output terminal of the peak amplifier 12, the other end 2212A of the input side coil 221A is connected to the ground, one end 2221A of the output side coil 222A is connected to the other end 2122A of the output side coil 212A, and the other end 2222A of the output side coil 222A is connected to the ground.

Accordingly, the two signals (voltages) of the band A amplified by the carrier amplifier 11 and the peak amplifier 12 are combined by using the two transformers 21A and 22A, so that the phase shift circuit can be omitted.

### Modification Example 2 of Embodiment 1

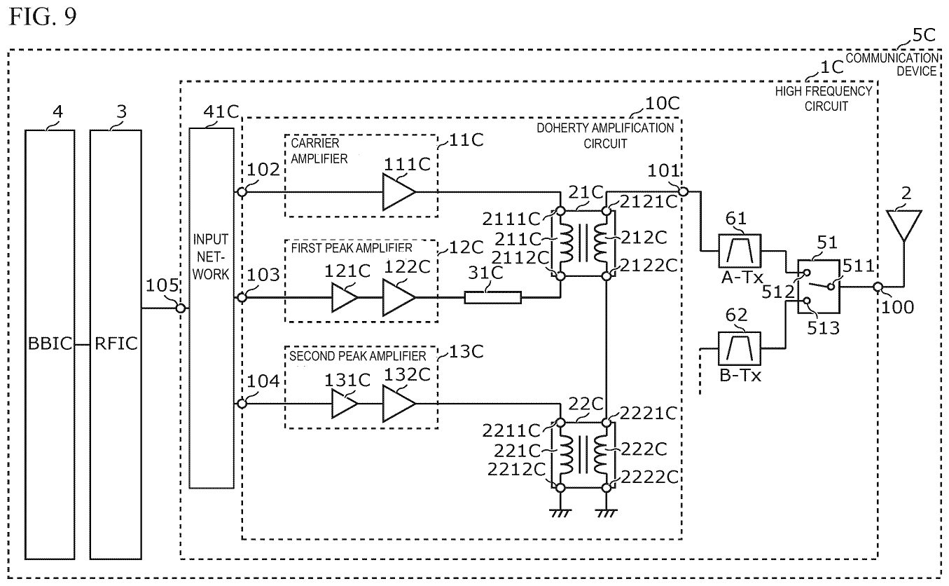

Next, Modification Example 2 of Embodiment 1 will be described. The present modification example is different from Embodiment 1 in that the output signal of the carrier amplifier 11 and the output signal of the peak amplifier 12 are subjected to current-combining without necessarily using the transformer. Hereinafter, the present modification example will be described with reference to FIG. 8, focusing on the difference from Embodiment 1.

FIG. 8 is a circuit configuration diagram of a Doherty amplification circuit 10B according to the present modification example. The Doherty amplification circuit 10B according to the present modification example is included in the high frequency circuit 1 of FIG. 1 instead of the Doherty amplification circuit 10.

As illustrated in FIG. 8, the Doherty amplification circuit 10B includes the carrier amplifier 11, the peak amplifier 12, a phase shift circuit 31B, the output terminal 101, and the input terminals 102 and 103.

The phase shift circuit 31B is connected between the output terminal of the carrier amplifier 11 and the output terminal 101 of the Doherty amplification circuit 10B. As a result, the output terminal of the carrier amplifier 11 is connected to the output terminal 101 with the phase shift circuit 31B interposed therebetween. On the other hand, the output terminal of the peak amplifier 12 is connected to the output terminal 101 without necessarily the phase shift circuit 31B interposed therebetween.

The phase shift circuit 31B can shift the phase of the signal of the band A output from the carrier amplifier 11 by −90 degrees (delay the phase of the signal of the band A output from the carrier amplifier 11 by 90 degrees). For example, a ¼ wavelength transmission line can be used as the phase shift circuit 31B. The phase shift circuit 31B may include an inductor and/or a capacitor. As a result, the phase shift circuit 31B can shorten a line length.

In a case where the Doherty amplification circuit 10B according to the present modification example is included in the high frequency circuit 1, for example, the input network 41 shifts the split signal of the band A output to the input terminal 102 by −90 degrees (delays the split signal of the band A output to the input terminal 102 by 90 degrees) from the input signal, and does not shift the split signal of the band A output to the input terminal 103 from the input signal.

As described above, the Doherty amplification circuit 10B according to the present modification example includes the phase shift circuit 31B that is connected between the output terminal of the carrier amplifier 11 and the output terminal 101 of the Doherty amplification circuit 10B, in which the output terminal of the carrier amplifier 11 is connected to the output terminal 101 of the Doherty amplification circuit 10B with the phase shift circuit 31B interposed therebetween, and the output terminal of the peak amplifier 12 is connected to the output terminal 101 of the Doherty amplification circuit 10B without necessarily the phase shift circuit 31B interposed therebetween.

Accordingly, two signals (currents) can be combined without necessarily using the transformer, and the Doherty amplification circuit 10B can be reduced in size.

### Embodiment 2

Next, Embodiment 2 will be described. The present embodiment is different from Embodiment 1 mainly in that the Doherty amplification circuit includes two peak amplifiers. Hereinafter, the present embodiment will be described focusing on the difference from Embodiment 1.

### 2.1 Circuit Configuration of High Frequency Circuit 1C

First, a high frequency circuit 1C provided in a communication device 5C according to the present embodiment will be described with reference to FIG. 9. FIG. 9 is a circuit configuration diagram of the communication device 5C according to the present embodiment. As illustrated in FIG. 9, the communication device 5C includes a high frequency circuit 1C, the antenna 2, the RFIC 3, and the BBIC 4.

The high frequency circuit 1C can transmit the high frequency signal between the antenna 2 and the RFIC 3. An internal configuration of the high frequency circuit 1C will be described below.

### 2.2 Circuit Configuration of High Frequency Circuit 1C

First, a circuit configuration of the high frequency circuit 1C included in the communication device 5C according to the present embodiment will be described with reference to FIG. 9. As illustrated in FIG. 9, the high frequency circuit 1C includes a Doherty amplification circuit 10C, an input network 41C, the switch 51, the filters 61 and 62, the antenna connection terminal 100, and the RFIC connection terminal 105. Hereinafter, an input network 41C different from that of Embodiment 1 will be described.

The input network 41C is connected between the RFIC connection terminal 105 and input terminals 102 to 104 of the Doherty amplification circuit 10C. The input network 41C functions as a power splitter and also functions as a phase shifter in the present embodiment.

Specifically, the input network 41C splits the transmission signal of the band A received via the RFIC connection terminal 105 into three signals, and outputs the split three signals (split signals) of the band A to the respective input terminals 102 to 104 of the Doherty amplification circuit 10C. In this case, the input network 41C adjusts the phases of the three split signals of the band A. For example, the input network 41C shifts the split signal of the band A output to the input terminals 102 and 104 by −90 degrees (delays the split signal of the band A output to the input terminals 102 and 104 by 90 degrees) from the input signal, and does not shift the split signal of the band A output to the input terminal 103 from the input signal.

A shift amount of the phase in the input network 41C is not limited to the above-described example. It is sufficient that a relative phase difference between the three split signals is maintained, and the shift amounts of the phases of the three split signals may be, for example, 0 degrees, +90 degrees, and 0 degrees. In addition, the phase difference between the three split signals may also be changed as appropriate based on an internal configuration of the Doherty amplification circuit 10C.

The high frequency circuit 1C represented in FIG. 9 is an example, and the high frequency circuit 1C is not limited thereto. For example, the high frequency circuit 1C need not include the filter 62 and the switch 51. In addition, the high frequency circuit 1C need not include the input network 41C. The high frequency circuit 1C may include a reception path. Further, for example, the high frequency circuit 1C may include a filter and a power amplification circuit corresponding to the band C different from the bands A and B.

### 2.3 Circuit Configuration of Doherty Amplification Circuit 10C

Here, a circuit configuration of the Doherty amplification circuit 10C included in the high frequency circuit 1C will be described with reference to FIG. 9. The Doherty amplification circuit 10C includes a carrier amplifier 11C, a first peak amplifier 12C, a second peak amplifier 13C, transformers 21C and 22C, a phase shift circuit 31C, the output terminal 101, and the input terminals 102 to 104. Hereinafter, the constituent elements of the Doherty amplification circuit 10C will be described in order.

The input terminals 102 to 104 are terminals for receiving the signal from the input network 41C. The transmission signal of the band A output from the input network 41C is input to the carrier amplifier 11C, the first peak amplifier 12C, and the second peak amplifier 13C with the input terminals 102 to 104 interposed therebetween.

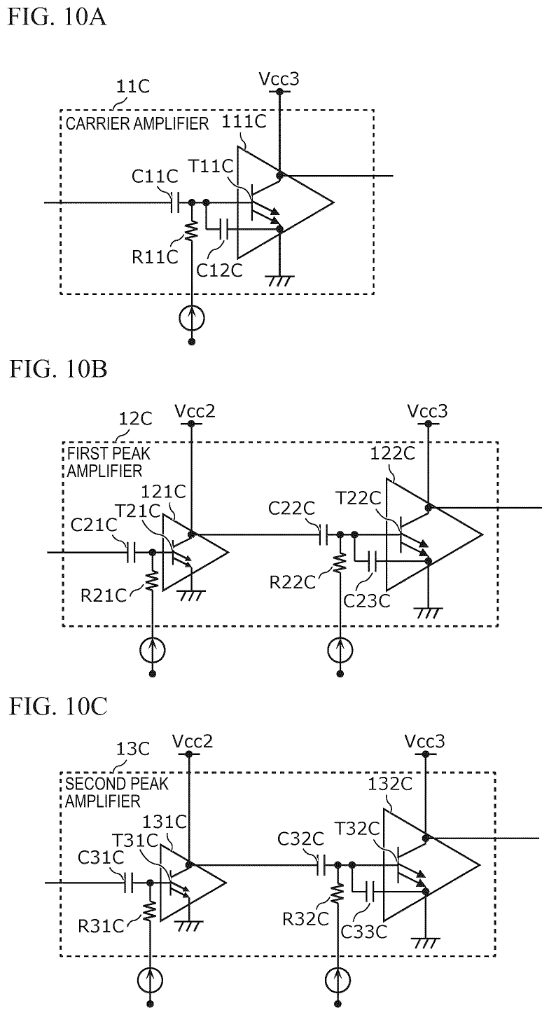

The carrier amplifier 11C is a single-stage amplifier, and includes a single stage 111C corresponding to the first stage and the final stage. Therefore, in the present embodiment, the number of stages of the carrier amplifier 11C is one. The carrier amplifier 11C can operate in, for example, a class-A or a class-AB to amplify the high frequency signal received via the input terminal 102. A circuit configuration of the carrier amplifier 11C will be described below with reference to FIG. 10A.

The first peak amplifier 12C is a multistage amplifier, and includes a first stage 121C (drive stage or input stage) and a final stage 122C (power stage or output stage). Therefore, in the present embodiment, the number of stages of the first peak amplifier 12C is two, which is larger than the number of stages of the carrier amplifier 11C. The first peak amplifier 12C can operate in, for example, a class-C to amplify the high frequency signal received via the input terminal 103. A circuit configuration of the first peak amplifier 12C will be described below with reference to FIG. 10B.

The second peak amplifier 13C is a multistage amplifier, and includes a first stage 131C (drive stage or input stage) and a final stage 132C (power stage or output stage). Therefore, in the present embodiment, the number of stages of the second peak amplifier 13C is two, which is larger than the number of stages of the carrier amplifier 11C. The second peak amplifier 13C can operate in, for example, a class-C to amplify the high frequency signal received via the input terminal 104. In this case, the power at which the on-state and the off-state are switched is set to be higher in the second peak amplifier 13C than in the first peak amplifier 12C. A circuit configuration of the second peak amplifier 13C will be described below with reference to FIG. 10C.

The transformer 21C is an example of a first transformer, and includes an input side coil 211C and an output side coil 212C. The input side coil 211C and the output side coil 212C are respective examples of a first input side coil and a first output side coil. One end 2111C of the input side coil 211C is connected to an output terminal of the carrier amplifier 11C. The other end 2112C of the input side coil 211C is connected to an output terminal of the first peak amplifier 12C with the phase shift circuit 31C interposed therebetween. One end 2121C of the output side coil 212C is connected to the output terminal 101. The other end 2122C of the output side coil 212C is connected to an output side coil 222C of the transformer 22C.

The transformer 22C is an example of a second transformer, and includes an input side coil 221C and the output side coil 222C. The input side coil 221C and the output side coil 222C are respective examples of a second input side coil and a second output side coil. One end 2211C of the input side coil 221C is connected to an output terminal of the second peak amplifier 13C. The other end 2212C of the input side coil 221C is connected to the ground. One end 2221C of the output side coil 222C is connected to the other end 2122C of the output side coil 212C of the transformer 21C. The other end 2222C of the output side coil 222C is connected to the ground.

With this connection configuration, the transformers 21C and 22C can perform voltage-combining of the output signals of the carrier amplifier 11C, the first peak amplifier 12C, and the second peak amplifier 13C.

The phase shift circuit 31C is connected between the output terminal of the first peak amplifier 12C and the transformer 21C. The phase shift circuit 31C can shift the phase of the signal of the band A output from the first peak amplifier 12C by −90 degrees (delay the phase of the signal of the band A output from the first peak amplifier 12C by 90 degrees). For example, a ¼ wavelength transmission line can be used as the phase shift circuit 31C. The phase shift circuit 31C may include an inductor and/or a capacitor. As a result, the phase shift circuit 31C can shorten a line length.

The Doherty amplification circuit 10C represented in FIG. 9 is an example, and the Doherty amplification circuit 10C is not limited thereto. For example, the Doherty amplification circuit 10C may include a part or all of the input network 41C. The number of stages of the carrier amplifier 11C, the number of stages of the first peak amplifier 12C, and the number of stages of the second peak amplifier 13C are not limited to the above-described numbers (one, two, and two). For example, the number of stages of the carrier amplifier 11C may be two or more. Further, for example, the number of stages of the first peak amplifier 12C and the number of stages of the second peak amplifier 13C may be different from each other. In the present embodiment, it is sufficient that the condition of “the number of stages of the carrier amplifier 11C<the number of stages of the first peak amplifier 12C, and the number of stages of the carrier amplifier 11C<the number of stages of the second peak amplifier 13C” is satisfied.

### 2.4 Circuit Configurations of Carrier Amplifier 11C, First Peak Amplifier 12C, and Second Peak Amplifier 13C

Next, the circuit configurations of the carrier amplifier 11C, the first peak amplifier 12C, and the second peak amplifier 13C included in the Doherty amplification circuit 10C will be described in order.

First, the carrier amplifier 11C will be described with reference to FIG. 10A. FIG. 10A is a circuit configuration diagram of the carrier amplifier 11C according to the present embodiment.

The carrier amplifier 11C includes an amplification transistor T11C, capacitors C11C and C12C, and a resistor R11C.

The amplification transistor T11C is a bipolar transistor including a base terminal, a collector terminal, and an emitter terminal, and constitutes the single stage 111C of the carrier amplifier 11C. The base terminal of the amplification transistor T11C is connected to an input terminal of the carrier amplifier 11C with the capacitor C11C interposed therebetween, and is connected to a current source with the resistor R11C interposed therebetween. The collector terminal of the amplification transistor T11C is connected to the terminal to which the power supply voltage Vcc3 is applied, and is connected to the output terminal of the carrier amplifier 11C. The emitter terminal of the amplification transistor T11C is connected to the base terminal with the capacitor C12C interposed therebetween, and is connected to the ground.

Next, the first peak amplifier 12C will be described with reference to FIG. 10B. FIG. 10B is a circuit configuration diagram of the first peak amplifier 12C according to the present embodiment. The first peak amplifier 12C includes amplification transistors T21C and T22C, capacitors C21C to C23C, and resistors R21C and R22C.

The amplification transistor T21C is a bipolar transistor including a base terminal, a collector terminal, and an emitter terminal, and constitutes the first stage 121C of the first peak amplifier 12C. The base terminal of the amplification transistor T21C is connected to an input terminal of the first peak amplifier 12C with the capacitor C21C interposed therebetween, and is connected to the current source with the resistor R21C interposed therebetween. The collector terminal of the amplification transistor T21C is connected to the terminal to which the power supply voltage Vcc2 is applied, and is connected to an input terminal of the final stage 122C. The emitter terminal of the amplification transistor T21C is connected to the ground.

The amplification transistor T22C is a bipolar transistor including a base terminal, a collector terminal, and an emitter terminal, and constitutes the final stage 122C of the first peak amplifier 12C. The base terminal of the amplification transistor T22C is connected to an output terminal of the first stage 121C with the capacitor C22C interposed therebetween, and is connected to the current source with the resistor R22C interposed therebetween. The collector terminal of the amplification transistor T22C is connected to the terminal to which the power supply voltage Vcc3 is applied, and is connected to the output terminal of the first peak amplifier 12C. The emitter terminal of the amplification transistor T22C is connected to the base terminal with the capacitor C23C interposed therebetween, and is connected to the ground.

Next, the second peak amplifier 13C will be described with reference to FIG. 10C. FIG. 10C is a circuit configuration diagram of the second peak amplifier 13C according to the present embodiment. The second peak amplifier 13C includes amplification transistors T31C and T32C, capacitors C31C to C33C, and resistors R31C and R32C.

The amplification transistor T31C is a bipolar transistor including a base terminal, a collector terminal, and an emitter terminal, and constitutes the first stage 131C of the second peak amplifier 13C. The base terminal of the amplification transistor T31C is connected to an input terminal of the second peak amplifier 13C with the capacitor C31C interposed therebetween, and is connected to the current source with the resistor R31C interposed therebetween. The collector terminal of the amplification transistor T31C is connected to the terminal to which the power supply voltage Vcc2 is applied, and is connected to an input terminal of the final stage 132C. The emitter terminal of the amplification transistor T31C is connected to the ground.

The amplification transistor T32C is a bipolar transistor including a base terminal, a collector terminal, and an emitter terminal, and constitutes the final stage 132C of the second peak amplifier 13C. The base terminal of the amplification transistor T32C is connected to an output terminal of the first stage 131C with the capacitor C32C interposed therebetween, and is connected to the current source with the resistor R32C interposed therebetween. The collector terminal of the amplification transistor T32C is connected to the terminal to which the power supply voltage Vcc3 is applied, and is connected to the output terminal of the second peak amplifier 13C. The emitter terminal of the amplification transistor T32C is connected to the base terminal with the capacitor C33C interposed therebetween, and is connected to the ground.

The circuit configurations of the carrier amplifier 11C, the first peak amplifier 12C, and the second peak amplifier 13C represented in FIGS. 10A to 10C are examples, and the circuit configurations thereof are not limited thereto. For example, each of the amplification transistors T11C, T21C, T22C, T31C, and T32C may be a field effect transistor including a drain, a source, and a gate. Further, for example, an impedance matching circuit may be inserted between the stages in the first peak amplifier 12C and the second peak amplifier 13C. In this case, the impedance matching circuit may include an inductor and/or a capacitor, or may include a transformer.

### 2.5 Gain of Doherty Amplification Circuit 10C

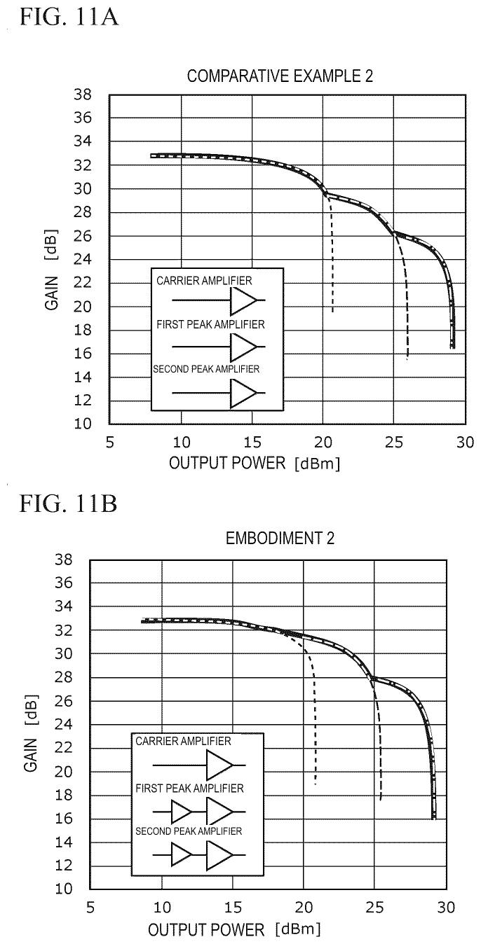

Next, gain of the Doherty amplification circuit 10C configured as described above will be described with reference to FIGS. 11A and 11B. FIG. 11A is a graph illustrating a change in gain with respect to output power of a Doherty amplification circuit according to Comparative Example 2. FIG. 11B is a graph illustrating a change in the gain with respect to the output power of the Doherty amplification circuit 10C according to the present embodiment. In FIGS. 11A and 11B, a horizontal axis represents the output power (dBm), and a vertical axis represents the gain (dB). In addition, a broken line graph represents the change in the gain with respect to the output power in each amplifier unit.

The Doherty amplification circuit according to Comparative Example 2 has the same configuration as that of the present embodiment, except that the carrier amplifier, the first peak amplifier, and the second peak amplifier have the equal number of stages, that is, one.

In Comparative Example 2, as illustrated in FIG. 11A, the change in the gain with respect to the output power is large in the vicinity of the output power of 20 dBm at which the on-state and the off-state of the first peak amplifier are switched, and in the vicinity of the output power of 25 dBm at which the on-state and the off-state of the second peak amplifier are switched. That is, the decrease amount of the gain of the Doherty amplification circuit in a case where each of the first peak amplifier and the second peak amplifier is switched from the off-state to the on-state is large. In other words, the increase amount of the gain of the Doherty amplification circuit in a case where each of the first peak amplifier and the second peak amplifier is switched from the on-state to the off-state is large.

On the other hand, in the present embodiment, as the number of stages of the first peak amplifier 12C and the number of stages of the second peak amplifier 13C are increased, the gain of the first peak amplifier 12C in the vicinity of the output power of 20 dBm and the gain of the second peak amplifier 13C in the vicinity of the output power of 25 dBm are both increased. Therefore, as illustrated in FIG. 11B, the change in the gain with respect to the output power in the vicinity of the output power of 20 dBm and 25 dBm is smaller than that in Comparative Example 2. That is, in the present embodiment, the decrease amount of the gain of the Doherty amplification circuit 10C in a case where each of the first peak amplifier 12C and the second peak amplifier 13C is switched from the off-state to the on-state is smaller than that in Comparative Example 2. Conversely, in the present embodiment, the increase amount of the gain of the Doherty amplification circuit 10C in a case where each of the first peak amplifier 12C and the second peak amplifier 13C is switched from the on-state to the off-state is smaller than that in Comparative Example 2.

As described above, the Doherty amplification circuit 10C according to the present embodiment can suppress the change in the gain with respect to the output power as compared with the Doherty amplification circuit according to Comparative Example 2. As a result, the Doherty amplification circuit 10C according to the present embodiment can suppress the deterioration in the characteristics as compared with the Doherty amplification circuit according to Comparative Example 2.

### 2.6 Mounting Examples of Carrier Amplifier 11C, First Peak Amplifier 12C, and Second Peak Amplifier 13C

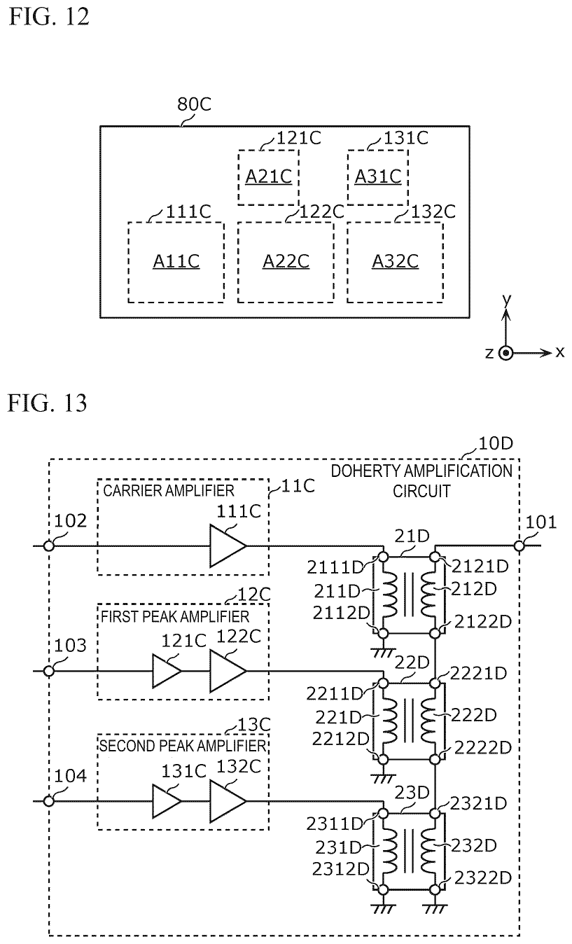

Next, mounting examples of the carrier amplifier 11C, the first peak amplifier 12C, and the second peak amplifier 13C will be described with reference to FIG. 12. FIG. 12 is a plan view of an integrated circuit 80C in which the carrier amplifier 11C, the first peak amplifier 12C, and the second peak amplifier 13C according to the present embodiment are mounted.

In FIG. 12, a region surrounded by a broken line represents a region in which the amplification transistors constituting each stage of the carrier amplifier 11C, the first peak amplifier 12C, and the second peak amplifier 13C in the integrated circuit 80C are formed. Specifically, in FIG. 12, the single stage 111C in the integrated circuit 80C represents a region in which the amplification transistor T11C is formed. Similarly, the first stage 121C and the final stage 122C in the integrated circuit 80C respectively represent a region in which the amplification transistor T21C is formed and a region in which the amplification transistor T22C is formed. Similarly, the first stage 131C and the final stage 132C in the integrated circuit 80C respectively represent a region in which the amplification transistor T31C is formed and a region in which the amplification transistor T32C is formed.

A size of the first peak amplifier 12C of the final stage 122C is larger than a size of the first stage 121C of the first peak amplifier 12C. That is, in plan view of the module substrate 90, an area of a region A22C in which the amplification transistor T22C is formed in the integrated circuit 80C is larger than an area of a region A21C in which the amplification transistor T21C is formed in the integrated circuit 80C.

A size of the final stage 132C of the second peak amplifier 13C is larger than a size of the first stage 131C of the second peak amplifier 13C. That is, in plan view of the module substrate 90, an area of a region A32C in which the amplification transistor T32C is formed in the integrated circuit 80C is larger than an area of a region A31C in which the amplification transistor T31C is formed in the integrated circuit 80C.

Each of the size of the first stage 121C of the first peak amplifier 12C and the size of the first stage 131C of the second peak amplifier 13C is smaller than a size of the single stage 111C (that corresponds to the first stage) of the carrier amplifier 11C. That is, in plan view of the module substrate 90, a size of the region A21C in which the amplification transistor T21C is formed in the integrated circuit 80C and a size of the region A31C in which the amplification transistor T31C is formed in the integrated circuit 80C are smaller than an area of a region A11C in which the amplification transistor T11C is formed in the integrated circuit 80C.

Each of the size of the first peak amplifier 12C of the final stage 122C and the size of the second peak amplifier 13C of the final stage 132C is equal to the size of the single stage 111C (that corresponds to the final stage) of the carrier amplifier 11C. That is, in plan view of the module substrate 90, a size of the region A22C in which the amplification transistor T22C is formed in the integrated circuit 80C and a size of the region A32C in which the amplification transistor T32C is formed in the integrated circuit 80C are equal to the area of the region A11C in which the amplification transistor T11C is formed in the integrated circuit 80C.

### 2.7 Effects

As described above, the Doherty amplification circuit 10C according to the present embodiment includes the carrier amplifier 11C that is a single-stage amplifier and the first peak amplifier 12C that is a multistage amplifier, in which the number of stages of the first peak amplifier 12C is larger than the number of stages of the carrier amplifier 11C.

Accordingly, the number of stages of the first peak amplifier 12C is larger than the number of stages of the carrier amplifier 11C, and thus the gain of the first peak amplifier 12C can be relatively increased. Therefore, it is possible to suppress the change in the gain of the Doherty amplification circuit 10C in a case where the on-state and the off-state of the first peak amplifier 12C are switched. As a result, the linearity of the Doherty amplification circuit 10C can be improved, and the deterioration in the characteristics can be suppressed.

Further, for example, the Doherty amplification circuit 10C according to the present embodiment may include the second peak amplifier 13C that is a multistage amplifier, in which the number of stages of the second peak amplifier 13C may be larger than the number of stages of the carrier amplifier 11C.

Accordingly, the number of stages of the second peak amplifier 13C is larger than the number of stages of the carrier amplifier 11C, and thus the gain of the second peak amplifier 13C can be relatively increased. Therefore, it is possible to suppress the change in the gain of the Doherty amplification circuit 10C in a case where the on-state and the off-state of the second peak amplifier 13C are switched. As a result, the linearity of the Doherty amplification circuit 10C can be improved, and the deterioration in the characteristics can be suppressed.

Further, for example, the Doherty amplification circuit 10C according to the present embodiment may include the module substrate 90, and at least one integrated circuit 80C that is disposed on the module substrate 90 and includes the carrier amplifier 11C, the amplification transistors T11C, T21C, T22C, T31C, and T32C of the first peak amplifier 12C and the second peak amplifier 13C, in which in plan view of the module substrate 90, the size of the amplification transistor T21C constituting the first stage 121C of the first peak amplifier 12C may be smaller than the size of the first stage (single stage 111C) of the carrier amplifier 11C, and the size of the first stage 131C of the second peak amplifier 13C may be smaller than the size of the first stage (single stage 111C) of the carrier amplifier 11C.

Accordingly, the size of the region A21C of the first stage 121C of the first peak amplifier 12C and the size of the region A31C of the first stage 131C of the second peak amplifier 13C can be made relatively small, the increase in the size of the integrated circuit 80C due to the increase in the number of stages of the first peak amplifier 12C and the second peak amplifier 13C can be suppressed.

Further, for example, in the Doherty amplification circuit 10C according to the present embodiment, in plan view of the module substrate 90, the size of the final stage 122C of the first peak amplifier 12C may be equal to the size of the final stage (single stage 111C) of the carrier amplifier 11C, and the size of the final stage 132C of the second peak amplifier 13C may be equal to the size of the final stage (single stage 111C) of the carrier amplifier 11C.

As a result, the increase in the size of the region A22C of the final stage 122C of the first peak amplifier 12C and the final stage 132C of the second peak amplifier 13C can be suppressed, and the decrease in the gain of each of the first peak amplifier 12C and the second peak amplifier 13C can be suppressed. Therefore, it is possible to suppress the change in the gain of the Doherty amplification circuit 10C in a case where the on-state and the off-state of each of the first peak amplifier 12C and the second peak amplifier 13C are switched. As a result, the linearity of the Doherty amplification circuit 10C can be improved, and the deterioration in the characteristics can be suppressed.

Further, for example, a Doherty amplification circuit 10C according to the present embodiment may include the transformer 21C including the input side coil 211C and the output side coil 212C, the transformer 22C including the input side coil 221C and the output side coil 222C, and the phase shift circuit 31C that is connected between the output terminal of the first peak amplifier 12C and the transformer 21C, in which one end 2111C of the input side coil 211C may be connected to the output terminal of the carrier amplifier 11C, the other end 2112C of the input side coil 211C may be connected to the output terminal of the first peak amplifier 12C with the phase shift circuit 31C interposed therebetween, one end 2121C of the output side coil 212C may be connected to the output terminal 101 of the Doherty amplification circuit 10C, the other end 2122C of the output side coil 212C may be connected to the output side coil 222C, one end 2211C of the input side coil 221C may be connected to the output terminal of the second peak amplifier 13C, the other end 2212C of the input side coil 221C may be connected to the ground, one end 2221C of the output side coil 222C may be connected to the other end 2122C of the output side coil 212C, and the other end 2222C of the output side coil 222C may be connected to the ground.

Accordingly, the three signals (voltages) of the band A amplified by the carrier amplifier 11C, the first peak amplifier 12C, and the second peak amplifier 13C can be combined by using the two transformers 21C and 22C.

### Modification Example 1 of Embodiment 2

Next, Modification Example 1 of Embodiment 2 will be described. The present modification example is different from Embodiment 2 in that the output signal of the carrier amplifier 11C, the output signal of the first peak amplifier 12C, and the output signal of the second peak amplifier 13C are combined by using three transformers. Hereinafter, the present modification example will be described with reference to FIG. 13, focusing on the difference from Embodiment 2.

FIG. 13 is a circuit configuration diagram of a Doherty amplification circuit 10D according to the present modification example. The Doherty amplification circuit 10D according to the present modification example is included in the high frequency circuit 1C of FIG. 9 instead of the Doherty amplification circuit 10C.

As illustrated in FIG. 13, the Doherty amplification circuit 10D includes the carrier amplifier 11C, the first peak amplifier 12C, the second peak amplifier 13C, transformers 21D to 23D, the output terminal 101, and the input terminals 102 to 104.

The transformer 21D is an example of a first transformer, and includes an input side coil 211D and an output side coil 212D. The input side coil 211D and the output side coil 212D are respective examples of a first input side coil and a first output side coil. One end 2111D of the input side coil 211D is connected to the output terminal of the carrier amplifier 11C. The other end 2112D of the input side coil 211D is connected to the ground. One end 2121D of the output side coil 212D is connected to the output terminal 101. The other end 2122D of the output side coil 212D is connected to an output side coil 222D of the transformer 22D.

The transformer 22D is an example of a second transformer, and includes an input side coil 221D and the output side coil 222D. The input side coil 221D and the output side coil 222D are respective examples of a second input side coil and a second output side coil. One end 2211D of the input side coil 221D is connected to the output terminal of the first peak amplifier 12C. The other end 2212D of the input side coil 221D is connected to the ground. One end 2221D of the output side coil 222D is connected to the other end 2122D of the output side coil 212D of the transformer 21D. The other end 2222D of the output side coil 222D is connected to an output side coil 232D of the transformer 23D.

The transformer 23D is an example of a third transformer, and includes an input side coil 231D and the output side coil 232D. The input side coil 231D and the output side coil 232D are respective examples of a third input side coil and a third output side coil. One end 2311D of the input side coil 231D is connected to the output terminal of the second peak amplifier 13C. The other end 2312D of the input side coil 231D is connected to the ground. One end 2321D of the output side coil 232D is connected to the other end 2222D of the output side coil 222D of the transformer 22D. The other end 2322D of the output side coil 232D is connected to the ground.

With this connection configuration, the transformers 21D to 23D can perform voltage-combining of the output signals of the carrier amplifier 11C, the first peak amplifier 12C, and the second peak amplifier 13C.

In a case where the Doherty amplification circuit 10D according to the present modification example is included in the high frequency circuit 1C, for example, the input network 41C shifts the split signal of the band A output to the input terminal 102 by −180 degrees (delays the split signal of the band A output to the input terminal 102 by 180 degrees) from the input signal, and does not shift the split signal of the band A output to the input terminals 103 and 104 from the input signal.

As described above, the Doherty amplification circuit 10D according to the present modification example includes the transformer 21D including the input side coil 211D and the output side coil 212D, the transformer 22D including the input side coil 221D and the output side coil 222D, and the transformer 23D including the input side coil 231D and the output side coil 232D, in which one end 2111D of the input side coil 211D is connected to the output terminal of the carrier amplifier 11C, the other end 2112D of the input side coil 211D is connected to the ground, one end 2121D of the output side coil 212D is connected to the output terminal 101 of the Doherty amplification circuit 10D, the other end 2122D of the output side coil 212D is connected to the output side coil 222D, one end 2211D of the input side coil 221D is connected to the output terminal of the first peak amplifier 12C, the other end 2212D of the input side coil 221D is connected to the ground, one end 2221D of the output side coil 222D is connected to the other end 2122D of the output side coil 212D, the other end 2222D of the output side coil 222D is connected to the output side coil 232D, one end 2311D of the input side coil 231D is connected to the output terminal of the second peak amplifier 13C, the other end 2312D of the input side coil 231D is connected to the ground, one end 2321D of the output side coil 232D is connected to the other end 2222D of the output side coil 222D, and the other end 2322D of the output side coil 232D is connected to the ground.

Accordingly, the three signals (voltages) of the band A amplified by the carrier amplifier 11C, the first peak amplifier 12C, and the second peak amplifier 13C are combined by using the three transformers 21D to 23D, so that the phase shift circuit can be omitted.

### Modification Example 2 of Embodiment 2

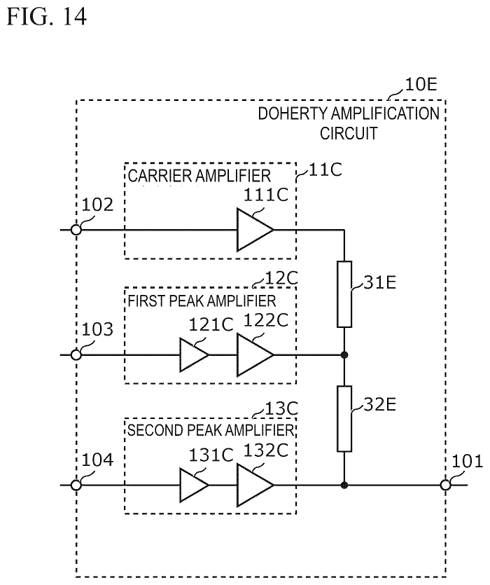

Next, Modification Example 2 of Embodiment 2 will be described. The present modification example is different from Embodiment 2 mainly in that the output signals of the carrier amplifier 11C, the first peak amplifier 12C, and the second peak amplifier 13C are subjected to current-combining without necessarily using the transformer. Hereinafter, the present modification example will be described with reference to FIG. 14, focusing on the difference from Embodiment 2.

FIG. 14 is a circuit configuration diagram of a Doherty amplification circuit 10E according to the present modification example. The Doherty amplification circuit 10E according to the present modification example is included in the high frequency circuit 1C of FIG. 9 instead of the Doherty amplification circuit 10C.

As illustrated in FIG. 14, the Doherty amplification circuit 10E includes the carrier amplifier 11C, the first peak amplifier 12C, the second peak amplifier 13C, phase shift circuits 31E and 32E, the output terminal 101, and the input terminals 102 to 104.

The phase shift circuit 31E is an example of a first phase shift circuit, and is connected between the output terminal of the carrier amplifier 11C and the output terminal 101 of the Doherty amplification circuit 10E. The phase shift circuit 31E can shift the phase of the signal of the band A output from the carrier amplifier 11C by −90 degrees (delay the phase of the signal of the band A output from the carrier amplifier 11C by 90 degrees).

For example, a ¼ wavelength transmission line can be used as the phase shift circuit 31E. The phase shift circuit 31E may include an inductor and/or a capacitor. As a result, the phase shift circuit 31E can shorten a line length.

The phase shift circuit 32E is an example of a second phase shift circuit, and is connected between the output terminal of the carrier amplifier 11C and the output terminal 101 of the Doherty amplification circuit 10E and between the output terminal of the first peak amplifier 12C and the output terminal 101 of the Doherty amplification circuit 10E. The phase shift circuit 32E can shift the phase of the signal of the band A output from each of the carrier amplifier 11C and the first peak amplifier 12C by −90 degrees (delay the phase of the signal of the band A output from each of the carrier amplifier 11C and the first peak amplifier 12C by 90 degrees). For example, a ¼ wavelength transmission line can be used as the phase shift circuit 32E. The phase shift circuit 32E may include an inductor and/or a capacitor. As a result, the phase shift circuit 32E can shorten a line length.

The output terminal of the carrier amplifier 11C is connected to the output terminal 101 with the phase shift circuits 31E and 32E interposed therebetween. The output terminal of the first peak amplifier 12C is connected to the output terminal 101 without necessarily the phase shift circuit 31E interposed therebetween and with the phase shift circuit 32E interposed therebetween. The output terminal of the second peak amplifier 13C is connected to the output terminal 101 without necessarily the phase shift circuits 31E and 32E interposed therebetween.

In a case where the Doherty amplification circuit 10E according to the present modification example is included in the high frequency circuit 1C, for example, the input network 41C does not shift the split signal of the band A output to the input terminal 102 from the input signal, shifts the split signal of the band A output to the input terminal 103 by +90 degrees (advances the split signal of the band A output to the input terminal 103 by 90 degrees) from the input signal, and does not shift the split signal of the band A output to the input terminal 104 from the input signal.

As described above, the Doherty amplification circuit 10E according to the present modification example includes the phase shift circuit 31E that is connected between the output terminal of the carrier amplifier 11C and the output terminal 101 of the Doherty amplification circuit 10E, and the phase shift circuit 32E that is connected between the output terminal of the carrier amplifier 11C and the output terminal 101 of the Doherty amplification circuit 10E and between the first peak amplifier 12C and the output terminal 101 of the Doherty amplification circuit 10E, in which the output terminal of the carrier amplifier 11C is connected to the output terminal 101 of the Doherty amplification circuit 10E with the phase shift circuits 31E and 32E interposed therebetween, the output terminal of the first peak amplifier 12C is connected to the output terminal 101 of the Doherty amplification circuit 10E without necessarily the phase shift circuit 31E interposed therebetween and with the phase shift circuit 32E interposed therebetween, and the output terminal of the second peak amplifier 13C is connected to the output terminal 101 of the Doherty amplification circuit 10E without necessarily the phase shift circuits 31E and 32E interposed therebetween.

Accordingly, three signals (currents) can be combined without necessarily using the transformer, and the Doherty amplification circuit 10E can be reduced in size.

### Embodiment 3

Next, Embodiment 3 will be described. The present embodiment is different from Embodiment 2 mainly in that the number of stages of the second peak amplifier is larger than the number of stages of the first peak amplifier. Hereinafter, the present embodiment will be described focusing on the difference from Embodiment 2.

### 3.1 Circuit Configuration of Doherty Amplification Circuit 10F

A communication device 5F according to the present embodiment is the same as the communication device 5C, except that a high frequency circuit 1F is included instead of the high frequency circuit 1C, and thus the description thereof will be omitted. In addition, the high frequency circuit 1F is the same as the high frequency circuit 1C, except that the high frequency circuit 1F includes a Doherty amplification circuit 10F instead of the Doherty amplification circuit 10C, and thus the description thereof will be omitted.

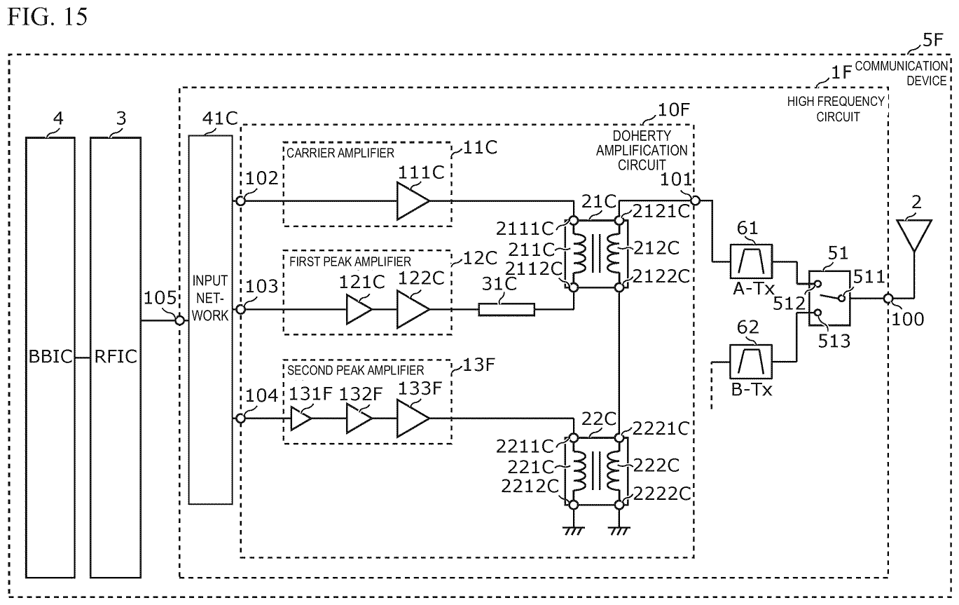

Therefore, a circuit configuration of the Doherty amplification circuit 10F according to the present embodiment will be described with reference to FIG. 15. FIG. 15 is a circuit configuration diagram of the communication device 5F according to the present embodiment. The Doherty amplification circuit 10F includes the carrier amplifier 11C, the first peak amplifier 12C, a second peak amplifier 13F, the transformers 21C and 22C, the phase shift circuit 31C, the output terminal 101, and the input terminals 102 to 104.

The second peak amplifier 13F is a multistage amplifier, and includes a first stage 131F (drive stage or input stage), a second stage 132F, and a final stage 133F (power stage or output stage). Therefore, in the present embodiment, the number of stages of the second peak amplifier 13F is three, which is larger than the number of stages of the carrier amplifier 11C and is larger than the number of stages of the first peak amplifier 12C. The second peak amplifier 13F can operate in, for example, a class-C to amplify the high frequency signal received via the input terminal 104. In this case, the power at which the on-state and the off-state are switched is set to be higher in the second peak amplifier 13F than in the first peak amplifier 12C.

The Doherty amplification circuit 10F represented in FIG. 15 is an example, and the Doherty amplification circuit 10F is not limited thereto. For example, the Doherty amplification circuit 10F may include a part or all of the input network 41C. The number of stages of the carrier amplifier 11C, the number of stages of the first peak amplifier 12C, and the number of stages of the second peak amplifier 13F are not limited to the above-described numbers (one, two, and three). For example, the number of stages of the carrier amplifier 11C may be two or more, the number of stages of the first peak amplifier 12C may be three or more, and the number of stages of the second peak amplifier 13F may be four or more. In the present embodiment, it is sufficient that the condition of “the number of stages of the carrier amplifier 11C<the number of stages of the first peak amplifier 12C<the number of stages of the second peak amplifier 13F”.

### 3.2 Circuit Configuration of Second Peak Amplifier 13F

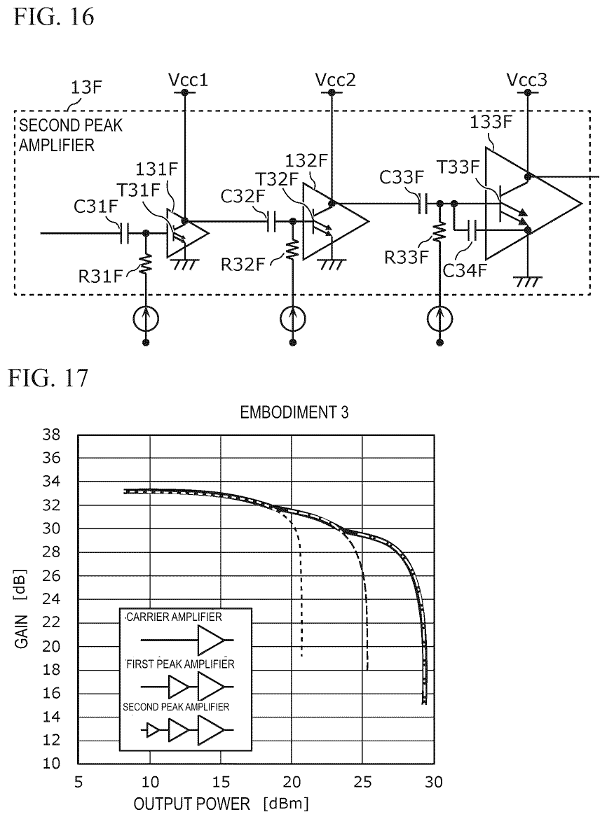

Next, a circuit configuration of the second peak amplifier 13F included in the Doherty amplification circuit 10F will be described with reference to FIG. 16. FIG. 16 is a circuit configuration diagram of the second peak amplifier 13F according to the present embodiment. The second peak amplifier 13F includes amplification transistors T31F to T33F, capacitors C31F and C34F, and resistors R31F to R33F. The amplification transistor T31F is a bipolar transistor including a base terminal, a collector terminal, and an emitter terminal, and constitutes the first stage 131F of the second peak amplifier 13F. The base terminal of the amplification transistor T31F is connected to an input terminal of the second peak amplifier 13F with the capacitor C31F interposed therebetween, and is connected to the current source with the resistor R31F interposed therebetween. The collector terminal of the amplification transistor T31F is connected to the terminal to which the power supply voltage Vcc1 is applied, and is connected to the input terminal of the second stage 132F. The emitter terminal of the amplification transistor T31F is connected to the ground.

The amplification transistor T32F is a bipolar transistor including a base terminal, a collector terminal, and an emitter terminal, and constitutes the second stage 132F of the second peak amplifier 13F. The base terminal of the amplification transistor T32F is connected to an output terminal of the first stage 131F with the capacitor C32F interposed therebetween, and is connected to the current source with the resistor R32F interposed therebetween. The collector terminal of the amplification transistor T32F is connected to the terminal to which the power supply voltage Vcc2 is applied, and is connected to an input terminal of the final stage 133F. The emitter terminal of the amplification transistor T32F is connected to the ground.

The amplification transistor T33F is a bipolar transistor including a base terminal, a collector terminal, and an emitter terminal, and constitutes the final stage 133F of the second peak amplifier 13F. The base terminal of the amplification transistor T33F is connected to an output terminal of the second stage 132F with the capacitor C33F interposed therebetween, and is connected to the current source with the resistor R33F interposed therebetween. The collector terminal of the amplification transistor T33F is connected to the terminal to which the power supply voltage Vcc3 is applied, and is connected to the output terminal of the second peak amplifier 13F. The emitter terminal of the amplification transistor T33F is connected to the base terminal with the capacitor C34F interposed therebetween, and is connected to the ground.

The circuit configuration of the second peak amplifier 13F represented in FIG. 16 is an example, and the circuit configuration thereof is not limited thereto. For example, each of the amplification transistors T31F to T33F may be a field effect transistor including a drain, a source, and a gate. Further, for example, an impedance matching circuit may be inserted between the stages of the second peak amplifier 13F. In this case, the impedance matching circuit may include an inductor and/or a capacitor, or may include a transformer.

### 3.3 Gain of Doherty Amplification Circuit 10F

Next, gain of the Doherty amplification circuit 10F configured as described above will be described with reference to FIG. 17. FIG. 17 is a graph illustrating a change in the gain with respect to the output power of the Doherty amplification circuit 10F according to the present embodiment. In FIG. 17, a horizontal axis represents the output power (dBm), and a vertical axis represents the gain (dB). In addition, a broken line graph represents the change in the gain with respect to the output power in each amplifier unit.

In the present embodiment, the gain of the second peak amplifier 13F in the vicinity of the output power of 25 dBm is further increased as the number of stages of the second peak amplifier 13F is increased. Therefore, the change in the gain with respect to the output power in the vicinity of the output power of 25 dBm is smaller than that in Embodiment 2 (FIG. 11B). That is, in the present embodiment, the decrease amount of the gain of the Doherty amplification circuit 10F in a case where the second peak amplifier 13F is switched from the off-state to the on-state is smaller than that in Embodiment 2. Conversely, in the present embodiment, the increase amount of the gain of the Doherty amplification circuit 10F in a case where the second peak amplifier 13F is switched from the on-state to the off-state is smaller than that in Embodiment 2.

As described above, the Doherty amplification circuit 10F according to the present embodiment can suppress the change in the gain with respect to the output power as compared with the Doherty amplification circuit according to Comparative Example 2 and the Doherty amplification circuit 10C according to Embodiment 2. As a result, the Doherty amplification circuit 10F according to the present embodiment can suppress the deterioration in the characteristics as compared with the Doherty amplification circuits according to Comparative Example 2 and Embodiment 2.

### 3.4 Mounting Examples of Carrier Amplifier 11C, First Peak Amplifier 12C, and Second Peak Amplifier 13F

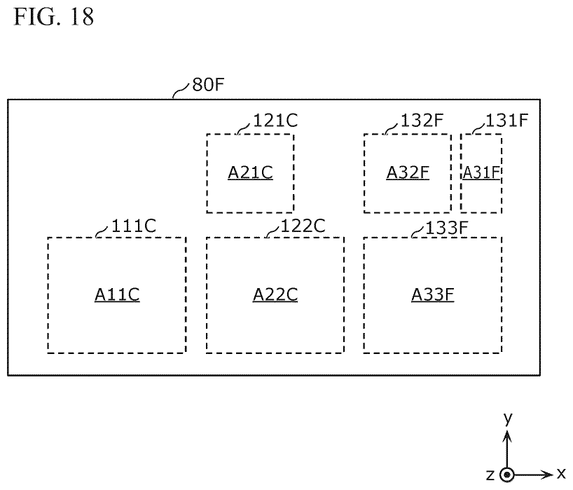

Next, mounting examples of the carrier amplifier 11C, the first peak amplifier 12C, and the second peak amplifier 13F will be described with reference to FIG. 18. FIG. 18 is a plan view of an integrated circuit 80F in which the carrier amplifier 11C, the first peak amplifier 12C, and the second peak amplifier 13F according to the present embodiment are mounted.

In FIG. 18, a region surrounded by a broken line represents a region in which the amplification transistors constituting each stage of the carrier amplifier 11C, the first peak amplifier 12C, and the second peak amplifier 13F in the integrated circuit 80F are formed. Specifically, in FIG. 18, the single stage 111C in the integrated circuit 80F represents the region in which the amplification transistor T11C is formed. Similarly, the first stage 121C and the final stage 122C in the integrated circuit 80F respectively represent the region in which the amplification transistor T21C is formed and the region in which the amplification transistor T22C is formed. Similarly, the first stage 131F, the second stage 132F, and the final stage 133F in the integrated circuit 80F respectively represent a region in which the amplification transistor T31F is formed, a region in which the amplification transistor T32F is formed, and a region in which the amplification transistor T33F is formed.

The size of the first peak amplifier 12C of the final stage 122C is larger than the size of the first stage 121C of the first peak amplifier 12C. That is, in plan view of the module substrate 90, the area of the region A22C in which the amplification transistor T22C is formed in the integrated circuit 80F is larger than the area of the region A21C in which the amplification transistor T21C is formed in the integrated circuit 80F.

A size of the final stage 133F of the second peak amplifier 13F is larger than a size of each of the first stage 131F and the second stage 132F of the second peak amplifier 13F. That is, in plan view of the module substrate 90, an area of a region A33F in which the amplification transistor T33F is formed in the integrated circuit 80F is larger than a size of an area of a region A31F in which the amplification transistor T31F is formed in the integrated circuit 80F and a region A32F in which the amplification transistor T32F is formed in the integrated circuit 80F. The size of the second stage 132F of the second peak amplifier 13F is larger than the size of the first stage 131F of the second peak amplifier 13F. That is, in plan view of the module substrate 90, an area of the region A32F in which the amplification transistor T32F is formed in the integrated circuit 80F is larger than an area of the region A31F in which the amplification transistor T31F is formed in the integrated circuit 80F.

Each of the size of the first stage 121C of the first peak amplifier 12C and the size of the first stage 131F of the second peak amplifier 13F is smaller than the size of the single stage 111C (that corresponds to the first stage) of the carrier amplifier 11C. Further, the size of the first stage 131F of the second peak amplifier 13F is smaller than the size of the first stage 121C of the first peak amplifier 12C. That is, in plan view of the module substrate 90, the area of the region A31F in which the amplification transistor T31F is formed in the integrated circuit 80F is smaller than the area of the region A21C in which the amplification transistor T21C is formed in the integrated circuit 80F, and the area of the region A21C in which the amplification transistor T21C is formed in the integrated circuit 80F is smaller than the area of the region A11C in which the amplification transistor T11C is formed in the integrated circuit 80F.

Each of the size of the first peak amplifier 12C of the final stage 122C and the size of the second peak amplifier 13F of the final stage 133F is equal to the size of the single stage 111C (that corresponds to the final stage) of the carrier amplifier 11C. That is, in plan view of the module substrate 90, the size of the region A22C in which the amplification transistor T22C is formed in the integrated circuit 80F and the size of the region A33F in which the amplification transistor T33F is formed in the integrated circuit 80F are equal to the area of the region A11C in which the amplification transistor T11C is formed in the integrated circuit 80F.

### 3.5 Effects

As described above, the Doherty amplification circuit 10F according to the present embodiment includes the carrier amplifier 11C that is a single-stage amplifier and the first peak amplifier 12C that is a multistage amplifier, in which the number of stages of the first peak amplifier 12C is larger than the number of stages of the carrier amplifier 11C.

Accordingly, the number of stages of the first peak amplifier 12C is larger than the number of stages of the carrier amplifier 11C, and thus the gain of the first peak amplifier 12C can be relatively increased. Therefore, it is possible to suppress the change in the gain of the Doherty amplification circuit 10F in a case where the on-state and the off-state of the first peak amplifier 12C are switched. As a result, the linearity of the Doherty amplification circuit 10F can be improved, and the deterioration in the characteristics can be suppressed.

Further, for example, the Doherty amplification circuit 10F according to the present embodiment may include the second peak amplifier 13F that is a multistage amplifier, in which the number of stages of the second peak amplifier 13F may be larger than the number of stages of the first peak amplifier 12C.

Accordingly, the number of stages of the second peak amplifier 13F is larger than the number of stages of the first peak amplifier 12C, and thus the gain of the second peak amplifier 13F can be further relatively increased. Therefore, it is possible to further suppress the change in the gain of the Doherty amplification circuit 10F in a case where the on-state and the off-state of the second peak amplifier 13F are switched. As a result, the linearity of the Doherty amplification circuit 10F can be further improved, and the deterioration in the characteristics can be further suppressed.

Further, for example, the Doherty amplification circuit 10F according to the present embodiment may include the module substrate 90, and at least one integrated circuit 80F that is disposed on the module substrate 90 and includes the amplification transistors T11C, T21C, T22C, and T31F to T33F of the carrier amplifier 11C, the first peak amplifier 12C, and the second peak amplifier 13F, in which in plan view of the module substrate 90, the size of the first stage 121C of the first peak amplifier 12C may be smaller than the size of the first stage (single stage 111C) of the carrier amplifier 11C, and the size of the first stage 131F of the second peak amplifier 13F may be smaller than the size of the first stage 121C of the first peak amplifier 12C.

As a result, the size of the first stage 121C of the first peak amplifier 12C and the size of the first stage 131F of the second peak amplifier 13F can be relatively reduced, so that the increase in the size of the integrated circuit 80F due to the increase in the number of stages of the first peak amplifier 12C and the second peak amplifier 13F can be suppressed. In particular, since the number of stages of the second peak amplifier 13F is larger than the number of stages of the first peak amplifier 12C, the increase in the size of the integrated circuit 80F due to the increase in the number of stages of the second peak amplifier 13F can be suppressed by making the size of the first stage 131F smaller than the size of the first stage 121C.

Further, for example, in the Doherty amplification circuit 10F according to the present embodiment, in plan view of the module substrate 90, the size of the final stage 122C of the first peak amplifier 12C may be equal to the size of the final stage (single stage 111C) of the carrier amplifier 11C, and the size of the final stage 133F of the second peak amplifier 13F may be equal to the size of the final stage (single stage 111C) of the carrier amplifier 11C.

As a result, the increase in the size of the region A22C of the final stage 122C of the first peak amplifier 12C and the final stage 133F of the second peak amplifier 13F can be suppressed, and the decrease in the gain of each of the first peak amplifier 12C and the second peak amplifier 13F can be suppressed. Therefore, it is possible to suppress the change in the gain of the Doherty amplification circuit 10F in a case where the on-state and the off-state of each of the first peak amplifier 12C and the second peak amplifier 13F are switched. As a result, the linearity of the Doherty amplification circuit 10F can be improved, and the deterioration in the characteristics can be suppressed.

Each of Modification Examples 1 and 2 of Embodiment 2 can also be applied to the present embodiment. That is, in Modification Examples 1 and 2 (FIGS. 13 and 14) of Embodiment 2, the second peak amplifier 13C may be replaced with the second peak amplifier 13F.

### OTHER EMBODIMENTS

Although the Doherty amplification circuit according to the present disclosure has been described based on the embodiments, the Doherty amplification circuit according to the present disclosure is not limited to the above-described embodiments. The present disclosure also includes another embodiment realized by combining any of the above-described constituent elements, a modification example obtained by various modifications conceived by those skilled in the art within a range not departing from the gist of the present disclosure with respect to the above-described embodiments, or various devices incorporating the above-described Doherty amplification circuit.

For example, in the circuit configurations of various circuits according to the above-described embodiments, other circuit elements, wirings, and the like may be inserted into the path connecting each circuit element and the signal path disclosed in the drawings. For example, an impedance matching circuit may be inserted between the Doherty amplification circuit and the filter and/or between the Doherty amplification circuit and the input network.

At least one of the circuit components of the high frequency circuit according to the above-described embodiments may be disposed on the module substrate of the Doherty amplification circuit. That is, the switch 51 and/or the filter 61 may be disposed on the module substrate 90.

The numbers of carrier amplifiers and the numbers of peak amplifiers of the Doherty amplification circuit according to each of the embodiments are examples, and are not limited to the above-described embodiments. For example, the Doherty amplification circuit may include two or more carrier amplifiers, or may include three or more peak amplifiers.

### INDUSTRIAL APPLICABILITY

The present disclosure can be widely used in a communication device such as a cellular phone as a Doherty amplification circuit capable of amplifying a high frequency signal.

### REFERENCE SIGNS LIST

1, 1C, 1F high frequency circuit
2 antenna
3 RFIC
4 BBIC
5, 5C, 5F communication device
10, 10A, 10B, 10C, 10D, 10E, 10F Doherty amplification circuit
11, 11C carrier amplifier
12 peak amplifier
12C first peak amplifier
13C, 13F second peak amplifier
21, 21A, 22A, 21C, 21D, 22C, 22D, 23D transformer
31, 31B, 31C, 31E, 32E phase shift circuit
41, 41C input network
51 switch
61, 62 filter
80, 80C, 80F integrated circuit
90 module substrate
90a, 90b main surface
100 antenna connection terminal
101 output terminal
102, 103, 104 input terminal
105 RFIC connection terminal
111, 121, 121C, 131C, 131F first stage
111C single stage
112, 122C, 123, 132C, 133F final stage
122, 132F second stage
150 land electrode
211, 211A, 211C, 211D, 221A, 221C, 221D, 231D input side coil
212, 212A, 212C, 212D, 222A, 222C, 222D, 232D output side coil
511, 512, 513 terminal
A11, A11C, A12, A21, A21C, A22, A22C, A23, A31C, A31F, A32C, A32F, A33F region
C11, C11C, C12, C12C, C13, C21, C21C, C22, C22C, C23, C23C, C24, C31C, C31F, C32C, C32F, C33C, C33F, C34F capacitor
R11, R11C, R12, R21, R21C, R22, R22C, R23, R31C, R31F, R32C, R32F, R33F resistor
T11, T11C, T12, T21, T21C, T22, T22C, T23, T31C, T31F, T32C, T32F, T33F amplification transistor
Vcc1, Vcc2, Vcc3 power supply voltage

1. A Doherty amplification circuit comprising:
a carrier amplifier that is a single-stage or multistage amplifier; and
a first peak amplifier that is a multistage amplifier,
wherein a number of stages of the first peak amplifier is greater than a number of stages of the carrier amplifier.

2. The Doherty amplification circuit according to claim 1, further comprising:
a module substrate; and
at least one integrated circuit that is on the module substrate and that comprises amplification transistors of the carrier amplifier and the first peak amplifier,
wherein in plan view of the module substrate, a size of a first stage of the first peak amplifier is smaller than a size of a first stage of the carrier amplifier.

3. The Doherty amplification circuit according to claim 1, further comprising:
a module substrate; and
at least one integrated circuit that is on the module substrate and that comprises amplification transistors of the carrier amplifier and the first peak amplifier,
wherein in plan view of the module substrate, a size of a final stage of the first peak amplifier is equal to a size of a final stage of the carrier amplifier.

4. The Doherty amplification circuit according to claim 1,
wherein one of the number of stages of the carrier amplifier or the number of stages of the first peak amplifier is odd, and
wherein another of the number of stages of the carrier amplifier or the number of stages of the first peak amplifier is even.

5. The Doherty amplification circuit according to claim 1, further comprising:
a transformer comprising an input side coil and an output side coil; and
a phase shift circuit that is connected between an output terminal of the first peak amplifier and the transformer,
wherein a first end of the input side coil is connected to an output terminal of the carrier amplifier,
wherein a second end of the input side coil is connected to the output terminal of the first peak amplifier with the phase shift circuit interposed between the second end of the input side coil and the output terminal of the first peak amplifier,
wherein a first end of the output side coil is connected to an output terminal of the Doherty amplification circuit, and
wherein a second end of the output side coil is connected to ground.

6. The Doherty amplification circuit according to claim 1, further comprising:
a first transformer comprising a first input side coil and a first output side coil; and
a second transformer comprising a second input side coil and a second output side coil,
wherein a first end of the first input side coil is connected to an output terminal of the carrier amplifier,
wherein a second end of the first input side coil is connected to ground,
wherein a first end of the first output side coil is connected to an output terminal of the Doherty amplification circuit,
wherein a second end of the first output side coil is connected to the second output side coil,
wherein a first end of the second input side coil is connected to an output terminal of the first peak amplifier,
wherein a second end of the second input side coil is connected to ground,
wherein a first end of the second output side coil is connected to the second end of the first output side coil, and
wherein a second end of the second output side coil is connected to ground.

7. The Doherty amplification circuit according to claim 1, further comprising:
a phase shift circuit that is connected between an output terminal of the carrier amplifier and an output terminal of the Doherty amplification circuit,
wherein the output terminal of the carrier amplifier is connected to the output terminal of the Doherty amplification circuit with the phase shift circuit interposed between the output terminal of the carrier amplifier and the output terminal of the Doherty amplification circuit, and
wherein an output terminal of the first peak amplifier is connected to the output terminal of the Doherty amplification circuit without the phase shift circuit interposed between the output terminal of the first peak amplifier and the output terminal of the Doherty amplification circuit.

8. The Doherty amplification circuit according to claim 1, further comprising:
a second peak amplifier that is a multistage amplifier,
wherein a number of stages of the second peak amplifier is greater than the number of stages of the carrier amplifier.

9. The Doherty amplification circuit according to claim 8, further comprising:
a module substrate; and
at least one integrated circuit that is on the module substrate and that comprises amplification transistors of the carrier amplifier, the first peak amplifier, and the second peak amplifier,
wherein in plan view of the module substrate, a size of a first stage of the first peak amplifier is smaller than a size of a first stage of the carrier amplifier, and a size of a first stage of the second peak amplifier is smaller than the size of the first stage of the carrier amplifier.

10. The Doherty amplification circuit according to claim 8,
wherein the number of stages of the second peak amplifier is greater than the number of stages of the first peak amplifier.

11. The Doherty amplification circuit according to claim 10, further comprising:
a module substrate; and
at least one integrated circuit that is on the module substrate and that comprises amplification transistors of the carrier amplifier, the first peak amplifier, and the second peak amplifier,
wherein in plan view of the module substrate, a size of a first stage of the first peak amplifier is smaller than a size of a first stage of the carrier amplifier, and a size of a first stage of the second peak amplifier is smaller than the size of the first stage of the first peak amplifier.

12. The Doherty amplification circuit according to claim 8, further comprising:
a module substrate; and
at least one integrated circuit that is on the module substrate and that comprises amplification transistors of the carrier amplifier, the first peak amplifier, and the second peak amplifier,
wherein in plan view of the module substrate, a size of a final stage of the first peak amplifier is equal to a size of a final stage of the carrier amplifier, and a size of a final stage of the second peak amplifier is equal to the size of the final stage of the carrier amplifier.

13. The Doherty amplification circuit according to claim 8, further comprising:
a first transformer comprising a first input side coil and a first output side coil;
a second transformer comprising a second input side coil and a second output side coil; and
a phase shift circuit that is connected between an output terminal of the first peak amplifier and the first transformer,
wherein a first end of the first input side coil is connected to an output terminal of the carrier amplifier,
wherein a second end of the first input side coil is connected to the output terminal of the first peak amplifier with the phase shift circuit interposed between the second end of the first input side coil and the output terminal of the first peak amplifier,
wherein a first end of the first output side coil is connected to an output terminal of the Doherty amplification circuit,
wherein a second end of the first output side coil is connected to the second output side coil,
wherein a first end of the second input side coil is connected to an output terminal of the second peak amplifier,
wherein a second end of the second input side coil is connected to ground,
wherein a first end of the second output side coil is connected to the second end of the first output side coil, and
wherein a second end of the second output side coil is connected to ground.

14. The Doherty amplification circuit according to claim 8, further comprising:
a first transformer comprising a first input side coil and a first output side coil;
a second transformer comprising a second input side coil and a second output side coil; and
a third transformer comprising a third input side coil and a third output side coil,
wherein a first end of the first input side coil is connected to an output terminal of the carrier amplifier,
wherein a second end of the first input side coil is connected to ground,
wherein a first end of the first output side coil is connected to an output terminal of the Doherty amplification circuit,
wherein a second end of the first output side coil is connected to the second output side coil,
wherein a first end of the second input side coil is connected to an output terminal of the first peak amplifier,
wherein a second end of the second input side coil is connected to ground,
wherein a first end of the second output side coil is connected to the second end of the first output side coil,
wherein a second end of the second output side coil is connected to the third output side coil,
wherein a first end of the third input side coil is connected to an output terminal of the second peak amplifier,
wherein a second end of the third input side coil is connected to ground,
wherein a first end of the third output side coil is connected to the second end of the second output side coil, and
wherein a second end of the third output side coil is connected to ground.

15. The Doherty amplification circuit according to claim 8, further comprising:
a first phase shift circuit that is connected between an output terminal of the carrier amplifier and an output terminal of the Doherty amplification circuit; and
a second phase shift circuit that is connected between the output terminal of the carrier amplifier and the output terminal of the Doherty amplification circuit, and between the first peak amplifier and the output terminal of the Doherty amplification circuit,
wherein the output terminal of the carrier amplifier is connected to the output terminal of the Doherty amplification circuit with the first phase shift circuit and the second phase shift circuit interposed between the output terminal of the carrier amplifier and the output terminal of the Doherty amplification circuit,
wherein an output terminal of the first peak amplifier is connected to the output terminal of the Doherty amplification circuit without the first phase shift circuit interposed between the output terminal of the first peak amplifier and the output terminal of the Doherty amplification circuit, and with the second phase shift circuit interposed between the output terminal of the first peak amplifier and the output terminal of the Doherty amplification circuit, and
wherein an output terminal of the second peak amplifier is connected to the output terminal of the Doherty amplification circuit without the first phase shift circuit and the second phase shift circuit interposed between the output terminal of the second peak amplifier and the output terminal of the Doherty amplification circuit.
